(19) United States
(12) Patent Application Publication
(10) Pub. No.: US 2024/0145219 A1
(43) Pub. Date: May 2, 2024

(54) APPARATUS FOR MANUFACTURING DISPLAY DEVICE

(71) Applicant: SAMSUNG DISPLAY CO., LTD., YONGIN-SI (KR)

(72) Inventors: Min Gyu PARK, YONGIN-SI (KR); Sae Hong KIM, YONGIN-SI (KR); Jung Gon KIM, YONGIN-SI (KR); Kyung Joo MIN, YONGIN-SI (KR); Hee Yong LEE, YONGIN-SI (KR); Suk Jin JANG, YONGIN-SI (KR); Choel Min JANG, YONGIN-SI (KR)

(21) Appl. No.: 18/331,333

(22) Filed: Jun. 8, 2023

(30) Foreign Application Priority Data
Oct. 28, 2022 (KR) 10-2022-0140816

(51) Int. Cl. H01J 37/32; C23C 16/30; C23C 16/455

(52) U.S. Cl. CPC H01J 37/32449; C23C 16/30; C23C 16/45563; H01J 37/32458; H01J 2237/3321

(57) ABSTRACT

An apparatus for manufacturing a display device includes a gas exhaust unit and a gas spray unit. The gas exhaust unit includes first and second sidewalls disposed side by side along a first direction, and an upper plate disposed on the first and second sidewalls, a first partition disposed between the first and second sidewalls and extending away from a lower surface of the upper plate in a second direction. The gas spray unit includes first and second spray portions spraying first and second gases in the second direction. The first partition includes first and second surfaces, a third surface connecting the first surface to the second surface, first and second horizontal openings formed at the first and second surfaces, a first vertical opening formed at the third surface, and a first sub exhaust path connecting the first and second horizontal openings, and the first vertical opening with each other.

### CROSS-REFERENCE TO RELATED APPLICATION

This application claims priority from Korean Patent Application No. 10-2022-0140816 filed on Oct. 28, 2022, in the Korean Intellectual Property Office and all the benefits accruing therefrom under 35 U.S.C. 119, the contents of which in its entirety are herein incorporated by reference.

### BACKGROUND

### Technical Field

The present disclosure relates to an apparatus for manufacturing a display device.

### Description of the Related Art

With the advancement of multimedia, the importance of a display device has been increased. Examples of the display device include a liquid crystal display (LCD) device and an organic light emitting display (OLED) device.

The display device includes a plurality of thin films. There are a variety of methods of forming a thin film, and as one of the methods, a vapor deposition method has been widely used.

The vapor deposition method uses one or more gases as a raw material that will form a thin film. As deposition apparatuses using such a vapor deposition method, there are a chemical vapor deposition (CVD) apparatus, a physical vapor deposition (PVD) apparatus, an atomic layer deposition (ALD) apparatus, and the like.

Particularly, among the vapor deposition apparatuses, a space division type vapor deposition apparatus has an advantage of reducing a processing time owing to a fast film forming speed and easily stacking different types of films (for example, an inorganic film and an organic film).

### BRIEF SUMMARY

An object of the present disclosure is to provide an apparatus for manufacturing a display device, which minimizes mixture of residual gases by improving exhaust performance.

Another object of the present disclosure is to provide an apparatus for manufacturing a display device, which improves film forming uniformity.

Other object of the present disclosure is to provide an apparatus for manufacturing a display device, which minimizes danger of explosion according to mixture of emission gases during an exhaust process.

The objects of the present disclosure are not limited to those mentioned above and additional objects of the present disclosure, which are not mentioned herein, will be clearly understood by those skilled in the art from the following description of the present disclosure.

According to an aspect of the present disclosure, an apparatus for manufacturing a display device includes a gas exhaust unit, a gas spray unit, and a chamber. The gas exhaust unit includes a first sidewall and a second sidewall that face each other and are disposed side by side along a first direction, an upper plate disposed on the first sidewall and the second sidewall, a first partition disposed between the first sidewall and the second sidewall and extending away from a lower surface of the upper plate in a second direction different from the first direction, a first main exhaust path corresponding to a first space that is defined by the first sidewall, the first partition and the upper plate, and a second main exhaust path corresponding to a second space that is defined by the first partition, the second sidewall and the upper plate. The gas spray unit includes a first spray portion disposed in the first main exhaust path and spraying a first gas in the second direction, and a second spray portion disposed in the second main exhaust path and spraying a second gas in the second direction, the second gas being different from the first gas. The chamber surrounds the gas exhaust unit and the gas spray unit. The first partition includes a first surface facing the first spray portion, a second surface facing the second spray portion, a third surface connecting the first surface to the second surface, the third surface being spaced apart from a lower surface of the upper plate in the second direction, a first horizontal opening formed at the first surface, a second horizontal opening formed at the second surface, a first vertical opening formed at the third surface, and a first sub exhaust path connecting the first horizontal opening, the second horizontal opening, and the first vertical opening with each other.

In an embodiment, the first sub exhaust path includes a first vertical tunnel extending from the first vertical opening toward the lower surface of the upper plate in the second direction, a first horizontal tunnel connecting the first horizontal opening to the first vertical tunnel, and a second horizontal tunnel connecting the second horizontal opening to the first vertical tunnel.

In an embodiment, the first horizontal tunnel and the second horizontal tunnel are positioned at the same level relative to the third surface of the first partition, and are disposed to be closer to the upper plate than the third surface of the first partition.

In an embodiment, a length of the first horizontal tunnel and the second horizontal tunnel in the second direction may be shorter than a length of the first vertical tunnel in the second direction.

In an embodiment, a length, in the first direction, of the first vertical tunnel is greater than or equal to a length, in the first direction, of each of the first horizontal tunnel and the second horizontal tunnel.

In an embodiment, the first partition further includes a first sub partition disposed in the first sub exhaust path, and the first sub partition is configured to divide the first vertical tunnel into a first sub area and a second sub area.

In an embodiment, the first sub partition is configured to block the first horizontal tunnel from the second horizontal tunnel.

In an embodiment, a length, in the second direction, of the first sub partition is longer than a length, in the second direction, of the first vertical tunnel.

In an embodiment, the first gas emitted from the first spray portion may be emitted through the first sub area, and the second gas emitted from the second spray portion may be emitted through the second sub area.

In an embodiment, the apparatus for manufacturing a display device may further include a first emission pump connected to the first main exhaust path, and a second emission pump connected to the second main exhaust path, the first gas may be emitted by the first emission pump, and the second gas may be emitted by the second emission pump.

In an embodiment, the first spray portion includes a first nozzle for spraying the first gas toward the vertical opening in the second direction, the second spray portion includes a second nozzle for spraying the second gas to the vertical opening in the second direction, and the first horizontal opening and the second horizontal opening are positioned at a higher level than the first nozzle and the second nozzle in the second direction.

In an embodiment, the first vertical opening is positioned at a lower level than the first nozzle and the second nozzle in the second direction.

In an embodiment, the first horizontal opening includes a plurality of openings arranged along a straight line extending in a third direction different from the first direction and the second direction.

In an embodiment, the first horizontal opening may include one opening extended along a third direction different from the first direction and the second direction.

In an embodiment, the first gas may be a reaction gas or a source gas, and the second gas may be the source gas when the first gas is the reaction gas, and may be the reaction gas when the first gas is the source gas.

In an embodiment, the reaction gas may be N₂ gas or H₂ gas, the source gas may be SiH₄ gas when the reaction gas is the N₂ gas, and may be HMDSO gas when the reaction gas is the H₂ gas.

In an embodiment, the apparatus for manufacturing a display device may further comprise a first storage tank for storing the first gas and a second storage tank for storing the second gas, the first storage tank may be connected to the first spray portion, and the second storage tank may be connected to the second spray portion.

According to an aspect of the present disclosure, an apparatus for manufacturing a display device includes a gas exhaust unit including a plurality of main exhaust paths respectively partitioned by a plurality of partitions disposed side by side along a first direction, a gas spray unit including a plurality of spray portions respectively disposed in the plurality of main exhaust paths and configured to spray gas in a second direction different from the first direction, a moving unit disposed below the gas exhaust unit and the gas spray unit and configured to move a substrate, a chamber surrounding the gas exhaust unit, the gas spray unit, and the moving unit, wherein the moving unit is configured to move the substrate in a space of the chamber under the gas exhaust unit, a gas supply unit connected to the gas spray unit and configured to supply gas to the gas spray unit, and a gas emission unit connected to the gas exhaust unit and configured to emit the gas exhausted from the gas exhaust unit to the outside. Each partition of the plurality of partitions includes a horizontal tunnel connecting adjacent main exhaust paths with each other among the main exhaust paths, and a vertical tunnel connecting the space of the chamber to the horizontal tunnel.

In an embodiment, each of the plurality of spray portions includes a nozzle directing toward the space of the chamber in which the moving unit moves, and the horizontal tunnel is positioned at a higher level in the second direction than the nozzle.

In an embodiment, a vertical length of the horizontal tunnel may be shorter than a vertical length of the vertical tunnel.

In the apparatus for manufacturing a display device according to one embodiment of the present disclosure, exhaust performance of the apparatus for manufacturing a display device may be improved so that mixture of residual gases may be minimized.

In the apparatus for manufacturing a display device according to an embodiment of the present disclosure, film forming uniformity may be improved.

In the apparatus for manufacturing a display device according to an embodiment of the present disclosure, danger of explosion according to mixture of emission gases may be minimized during an exhaust process.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic conceptual view illustrating an apparatus for manufacturing a display device according to one embodiment of the present disclosure;

FIG. 2 is a schematic perspective view illustrating a portion of an apparatus for manufacturing a display device according to one embodiment of the present disclosure;

FIG. 3 is a schematic conceptual view illustrating a gas supply unit and a gas spray unit according to one embodiment of the present disclosure;

FIG. 4 is a schematic conceptual view illustrating a gas emission unit and a gas exhaust unit according to one embodiment of the present disclosure;

FIG. 5 is a schematic cross-sectional view illustrating a gas spray unit taken along line I-I′ of FIG. 2;

FIG. 6 is a perspective view illustrating a first spray portion according to one embodiment of the present disclosure;

FIG. 7 is a bottom view illustrating a first spray portion according to one embodiment;

FIG. 8 is a schematic cross-sectional view illustrating a gas exhaust unit taken along line II-II′ of FIG. 2;

FIG. 9 is a perspective view illustrating a first partition according to one embodiment of the present disclosure;

FIG. 10 is a side view illustrating a first partition according to one embodiment of the present disclosure;

FIG. 11 is a cross-sectional view taken along line of FIG. 9;

FIG. 12 is a bottom view illustrating a first partition according to one embodiment of the present disclosure;

FIG. 13 is a schematic cross-sectional view illustrating a gas spray unit and a gas exhaust unit according to one embodiment of the present disclosure;

FIG. 14 is a bottom view illustrating a gas spray unit and a gas exhaust unit according to one embodiment of the present disclosure;

FIG. 15 is an enlarged view illustrating a portion ‘A’ of FIG. 13;

FIG. 16 is a cross-sectional view illustrating an operation state of an apparatus for manufacturing a display device according to one embodiment of the present disclosure;

FIG. 17 is a schematic perspective view illustrating a gas spray unit and a gas exhaust unit according to an embodiment of the present disclosure;

FIG. 18 is a bottom view illustrating a gas spray unit and a gas exhaust unit according to an embodiment of the present disclosure;

FIG. 19 is a perspective view illustrating a first partition according to an embodiment of the present disclosure;

FIG. 20 is a side view illustrating a first partition according to an embodiment of the present disclosure;

FIG. 21 is a schematic cross-sectional view illustrating a gas spray unit and a gas exhaust unit according to an embodiment of the present disclosure;

FIG. 22 is a bottom view illustrating a gas spray unit and a gas exhaust unit according to an embodiment of the present disclosure;

FIG. 23 is an enlarged view illustrating a portion ‘B’ of FIG. 21;

FIG. 24 is a view illustrating an operation state of an apparatus for manufacturing a display device according to an embodiment of the present disclosure;

FIG. 25 is a schematic conceptual view illustrating a gas emission unit and a gas exhaust unit according to an embodiment of the present disclosure;

FIGS. 26 to 28 are cross-sectional views illustrating a process of an apparatus for manufacturing a display device according to the above-described embodiments; and

FIG. 29 is a cross-sectional view illustrating a portion of a display device manufactured by an apparatus for manufacturing the display device according to the above-described embodiments.

### DETAILED DESCRIPTION OF THE DISCLOSURE

The present disclosure will now be described more fully hereinafter with reference to the accompanying drawings, in which embodiments of the present disclosure are shown. This present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, detailed embodiments will be described with reference to the accompanying drawings.

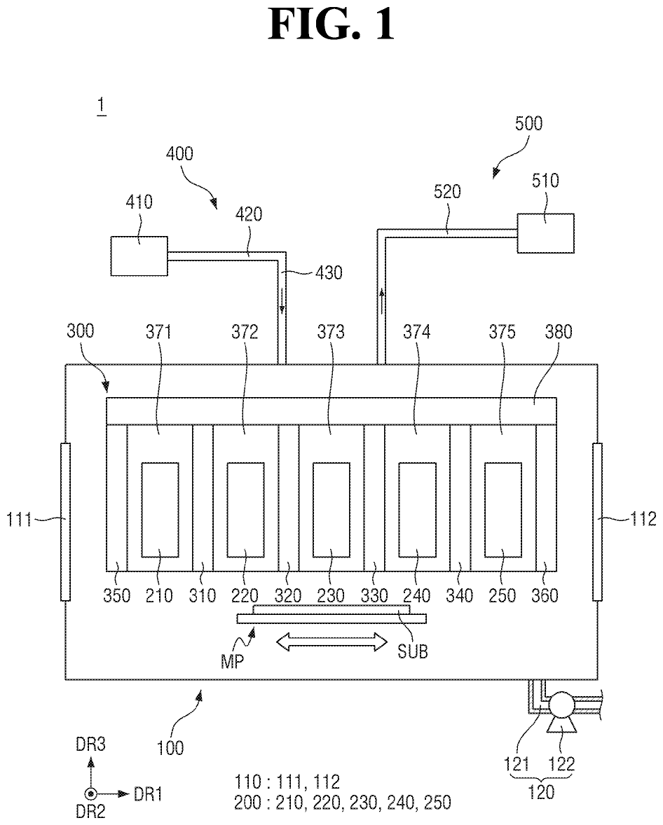

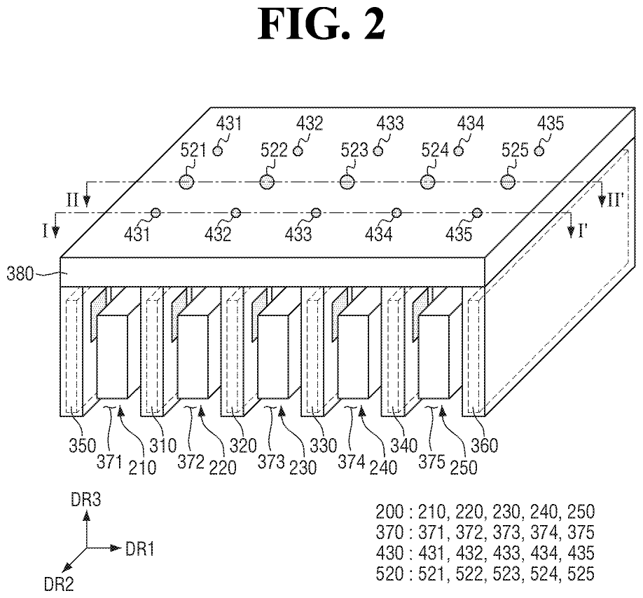

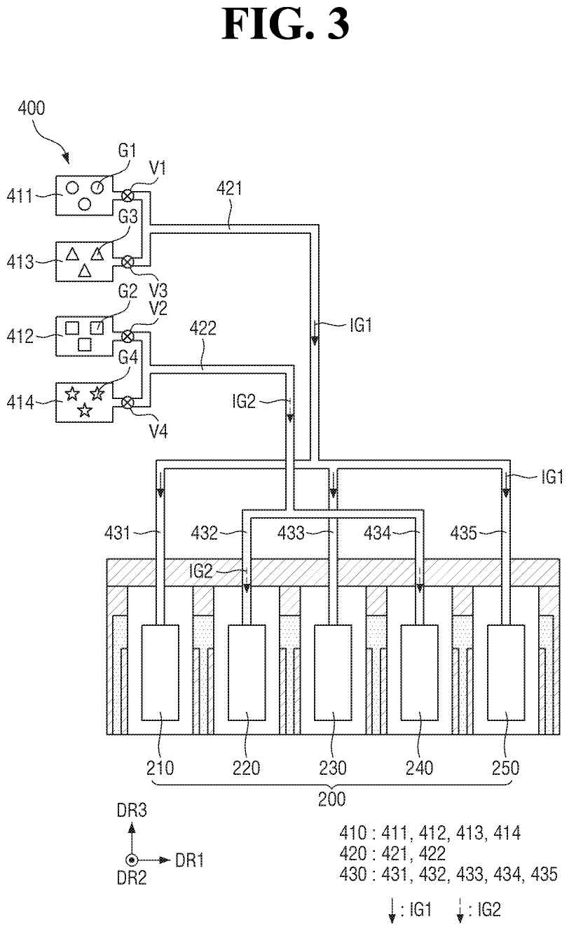

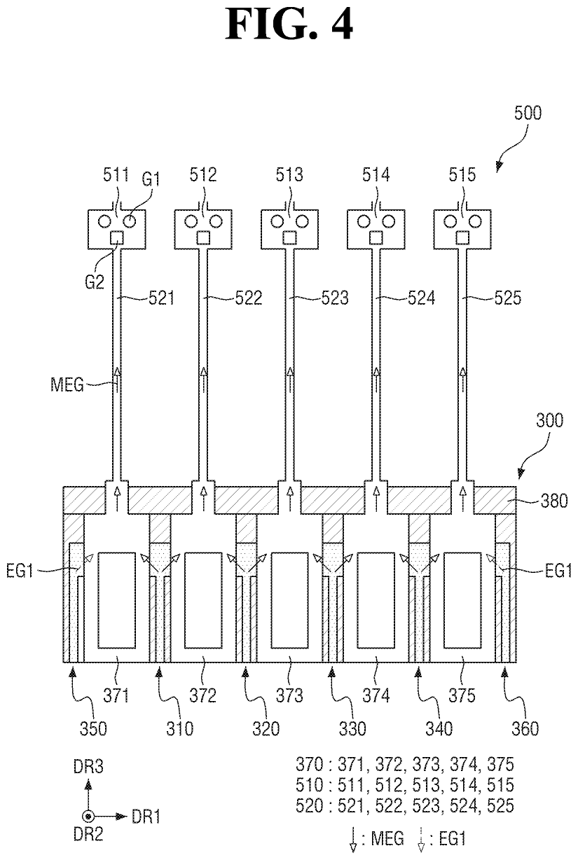

FIG. 1 is a schematic conceptual view illustrating an apparatus for manufacturing a display device according to one embodiment. FIG. 2 is a schematic perspective view illustrating a portion of an apparatus for manufacturing a display device according to one embodiment. FIG. 3 is a schematic conceptual view illustrating a gas supply unit and a gas spray unit according to one embodiment. FIG. 4 is a schematic conceptual view illustrating a gas emission unit and a gas exhaust unit according to one embodiment.

Referring to FIGS. 1 to 4, an apparatus 1 for manufacturing a display device is a type of vapor deposition apparatus, and may be an apparatus for depositing a plurality of thin films provided in the display device. For example, the apparatus may be an apparatus for manufacturing a display device, for forming at least one thin film layer of a thin metal film layer, thin oxide film layer, a thin nitride film layer, a thin carbide film layer or a thin sulfide film layer or a stacked structure thereof. In one embodiment, the apparatus 1 for manufacturing a display device may be a manufacturing apparatus for forming an inorganic layer, an organic layer and their staked layer, which are included in an encapsulation layer of the display device.

The apparatus 1 for manufacturing a display device may include a chamber 100, a gas spray unit 200, a gas exhaust unit 300, a gas supply unit 400 and a gas emission unit 500.

The chamber 100 may have a space formed therein and one side formed to be opened so that a substrate SUB may be ejected or accommodated. In one embodiment, a switching unit 110 including a gate valve may be disposed in the opened chamber 100 to selectively open and close the chamber 100. The switching unit 110 may include a first switching unit 111 for taking out the substrate SUB and a second switching unit 112 for carrying the substrate SUB into the chamber 100, but is not limited thereto. The substrate SUB may be carried into the chamber 100 through the first switching unit 111, may be taken out of the chamber 100 through the second switching unit 112, or may be taken out of the chamber 10 or carried into the chamber 100 through at least one of the first switching unit 111 and the second switching unit 112 without distinction of access.

In one embodiment, the chamber 100 may be a chamber for a chemical vapor deposition (CVD) method or a plasma enhanced chemical vapor deposition (PECVD) method. In an, the chamber may be a chamber capable of selectively performing the CVD method or the PECVD method.

The chamber 100 may further include a pressure controller 120 for adjusting a pressure thereinside. The pressure controller 120 may adjust the pressure inside the chamber 100 to be the same as or similar to an atmospheric pressure. In an embodiment, the pressure controller 120 may control the pressure inside the chamber 100 to be the same as or similar to a vacuum state. For example, the pressure controller 120 maintains a vacuum state while a process is being performed, and may maintain an atmospheric pressure state when the substrate SUB enters and exits.

The pressure controller 120 may include a pressure control pipe 121 communicated with the chamber 100 and a pressure control pump 122 installed at the pressure control pipe 121. The external air may flow through the pressure control pipe 121 in accordance with the operation of the pressure control pump 122, or the gas inside the chamber 100 may be guided to the outside through the pressure control pipe 121.

The gas spray unit 200 may emit a gas for forming a thin film, for example, an encapsulation layer, on the substrate SUB. The gas spray unit 200 may be disposed inside the chamber 100. The gas spray unit 200 may be fixed at an inside of the chamber 100. In an embodiment, the gas spray unit 200 may move inside the chamber 100.

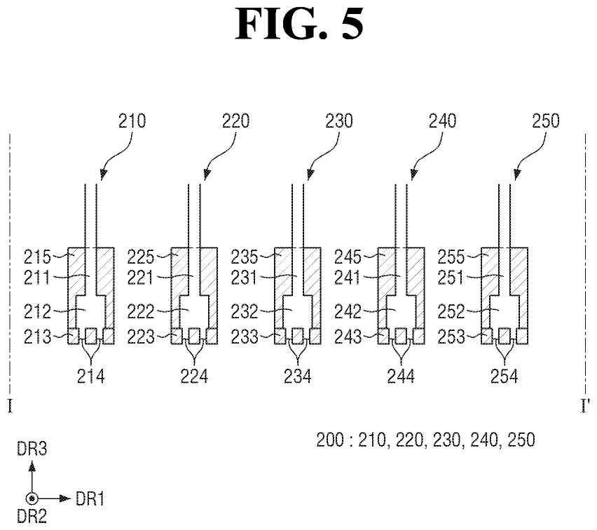

The gas spray unit 200 may include a plurality of spray portions. For example, as shown, the gas spray unit 200 may include first to fifth spray portions 210, 220, 230, 240 and 250, but the number of spray portions included in the gas spray unit 200 is not limited thereto and may be smaller or greater than five. In the present disclosure, for convenience of description, the case where the spray portions are is five will be described by way of example. A detailed description of the gas spray unit 200 will be described later with reference to FIGS. 5 to 7.

The gas exhaust unit 300 may exhaust the gas sprayed from the gas spray unit 200. A gas exhaust unit 300 may be disposed inside the chamber 100. The gas exhaust unit 300 may be fixed at the inside of the chamber 100. The gas exhaust unit 300 may move inside the chamber 100.

The gas exhaust unit 300 may include a plurality of partitions. For example, as shown, the gas exhaust unit 300 may include first to fourth partitions 310, 320, 330 and 340, but the number of partitions included in the gas exhaust unit 300 is not limited thereto and may be smaller or greater than four. For example, since the partitions and the spray portions of the gas spray unit 200 are alternately disposed, the number of partitions included in the gas exhaust unit 300 may be smaller than the number of spray portions as much as 1. As described above, since the case that the number of spray portions is five will be described by way of example, the case that the number of partitions is four will be described by way of example.

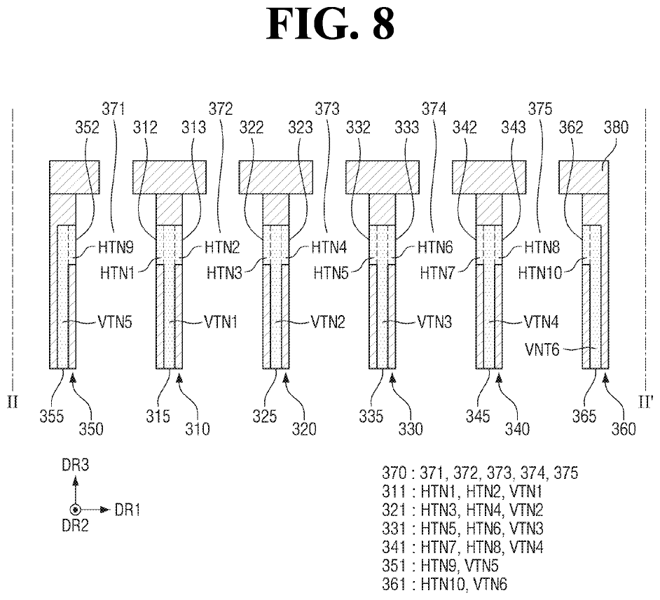

Each of the first to fourth partitions 310, 320, 330 and 340 of the gas exhaust unit 300 may include an opening and a tunnel connected to the opening. The opening and the tunnel will be described later in detail with reference to FIG. 8.

The gas exhaust unit 300 may further include first and second sidewalls 350 and 360, a main exhaust path 370 and an upper plate 380. The gas spray unit 200 may be disposed in the main exhaust path 370 formed by the first sidewall 350, the second sidewall 360 and the upper plate 380. The main exhaust path 370 may surround the gas spray unit 200. The spray portions 210, 220, 230, 240 and 250 of the gas spray unit 200 may be spaced apart from one another by the first to fourth partitions 310, 320, 330 and 340. The main exhaust path 370 may be divided into first to fifth main exhaust paths 371, 372, 373, 374 and 375 by the first to fourth partitions 310, 320, 330 and 340, respectively. The first to fifth spray portions 210, 220, 230, 240 and 250 may be positioned in the first to fifth main exhaust paths 371, 372, 373, 374 and 375, respectively. A detailed description of the gas exhaust unit 300 will be described in detail with reference to FIGS. 8 to 12.

Referring to FIG. 3, the gas supply unit 400 may supply a gas, which is a material of a process, to the gas spray unit 200. The gas supply unit 400 may include a storage tank 410, a common pipe 420 and a supply pipe 430.

The storage tank 410 may store a gas that is a material of a thin film deposition process. The storage tank 410 may include a plurality of storage tanks. For example, as shown, the storage tank 410 may include first to fourth storage tanks 411, 412, 413 and 414, but the number of storage tanks is not limited thereto and the number of storage tanks may vary depending on the number of types of gases that are materials of the process.

In one embodiment, the first storage tank 411 may store a first gas G1, the second storage tank 412 may store a second gas G2, the third storage tank 413 may store a third gas G3, and the fourth storage tank 414 may store a fourth gas G4.

The first gas G1 and the third gas G3 may be reaction gases that are materials for forming a thin film, and the second gas G2 and the fourth gas G4 may be source gases, that is, precursor gases, which serve as materials for forming a thin film.

In some embodiments, the first gas G1 and the second gas G2 may be gases that are materials of inorganic layer deposition, and the third gas G3 and the fourth gas G4 may be gases that are materials of organic layer deposition. For example, the first gas G1 may be a nitrogen (N₂) gas as a reaction gas for inorganic layer deposition, the second gas G2 may be a silane (SiH₄) gas as a source gas for inorganic layer deposition, the third gas G3 may be a hydrogen (H₂) gas as a reaction gas for organic layer deposition, and the fourth gas G4 may be a hexamethyldisiloxane (HMDSO) gas as a source gas for organic layer deposition.

The common pipe 420 may serve as a path for transferring the gas supplied from the storage tank 410 to a plurality of supply pipes 430 positioned inside the chamber 100. The gas supplied from the storage tank 410 may be distributed to the plurality of supply pipes 430 through the common pipe 420.

The common pipe 420 may include a first common pipe 421 and a second common pipe 422. The first common pipe 421 may be communicated with the first storage tank 411 and the third storage tank 413. The second common pipe 422 may be communicated with the second storage tank 412 and the fourth storage tank 414. The first common pipe 421 may be a path through which a first inflow gas IG1 moves, and the second common pipe 422 may be a path through which a second inflow gas IG2 moves.

The first inflow gas IG1 may be any one of the first gas G1 and the third gas G3, and the second inflow gas IG2 may be any one of the second gas G2 and the fourth gas G4. In one embodiment, when the first gas G1 flows into the chamber 100 through the first common pipe 421, the second gas G2 may flow into the chamber 100 through the second common pipe 422. When the third gas G3 flows into the chamber 100 through the first common pipe 421, the fourth gas G4 may flow into the chamber 100 through the second common pipe 422.

The supply pipe 430 may serve as a path for transferring the gas flowing from the common pipe 420 to the gas spray unit 200. The gas flowing from the common pipe 420 may be distributed to the first to fifth spray portions 210, 220, 230, 240 and 250 of the gas spray unit 200 through the supply pipe 430.

The supply pipe 430 may include a plurality of supply pipes. In one embodiment, as shown, the supply pipe 430 may include first to fifth supply pipes 431, 432, 433, 434 and 435. The first to fifth supply pipes 431, 432, 433, 434 and 435 may be directly communicated with the first to fifth spray portions 210, 220, 230, 240 and 250 without a physical boundary by passing through the upper plate 380 of the gas exhaust unit 300. The term “directly communicated with” may refer to a direct connection between two elements without any intervening element therebetween. The first supply pipe 431, the third supply pipe 433 and the fifth supply pipe 435 may be directly communicated with the first common pipe 421 without a physical boundary, and the second supply pipe 432 and the fourth supply pipe 434 may be directly communicated with the second common pipe 422 without a physical boundary.

The gas supply unit 400 may further include valves V1, V2, V3 and V4. The valves V1, V2, V3 and V4 may be disposed between the storage tanks 411, 412, 413 and 414 and the first and second common pipes 421 and 422. In one embodiment, the gas supply unit 400 may include first to fourth valves. The number of valves V1, V2, V3 and V4 may vary depending on the number of storage tanks 411, 412, 413 and 414. The first valve V1 may be connected to the first storage tank 411, the second valve V2 may be connected to the second storage tank 412, the third valve V3 may be connected to the third storage tank 413, and the fourth valve V4 may be connected to the fourth storage tank 414.

The valves V1, V2, V3 and V4 may be selectively opened and closed as needed. For example, when an inorganic layer deposition process is performed, the first valve V1 and the second valve V2 may be opened together, and when an organic layer deposition process is performed, the third valve V3 and the fourth valve V4 may be opened together.

Referring to FIG. 4, the gas emission unit 500 may emit the gas exhausted through the gas exhaust unit 300 to the outside of the chamber 100. The gas emission unit 500 may include an emission pump 510 and an emission pipe 520.

The emission pump 510 may be connected to at least one point of the emission pipe 520. The emission pump 510 may emit the gas exhausted from the gas exhaust unit 300 to the outside through the emission pipe 520. For example, an oil twin-sealed mechanical pump, a dry pump, a booster pump, a blower pump, a sorption pump, a venturi pump, a diffusion pump, a turbomolecular pump, a cryo pump, an ion pump, etc. may be used as the emission pump 510.

The emission pump 510 may include a plurality of emission pumps. In one embodiment, as shown, the emission pump 510 may include first to fifth emission pumps 511, 512, 513, 514 and 515, but the number of emission pumps 510 is not limited thereto and may vary depending on the number of spray portions 210, 220, 230, 240 and 250 of the gas spray unit 200. For example, the first to fifth emission pumps 511, 512, 513, 514 and 515 may be connected to the first to fifth spray portions 210, 220, 230, 240 and 250 in a one-to-one correspondence.

The emission pipe 520 may be communicated with an exhaust port (not shown) to serve as a path through which the gas exhausted from the gas exhaust unit 300 is emitted to the outside. The emission pipe 520 may include a plurality of emission pipes. In one embodiment, the emission pipe 520 may include first to fifth emission pipes 521, 522, 523, 524 and 525. The first to fifth emission pipes 521, 522, 523, 524 and 525 may be communicated with the first to fifth emission pumps 511, 512, 513, 514 and 515, respectively.

The emission pipe 520 may be directly communicated with the main exhaust path 370 without a physical boundary. In an embodiment, the emission pipe 520 may pass through the upper plate 380 of the gas exhaust unit 300. In one embodiment, the first to fifth emission pipes 521, 522, 523, 524 and 525 may be directly communicated with the first to fifth main exhaust paths 371, 372, 373, 374 and 375, respectively, without a physical boundary. In an embodiment, a portion of the emission pipe 520 may have a width greater than a width of the other portion of the emission pipe 520.

The apparatus 1 for manufacturing a display device may further include a moving unit MP for moving the substrate SUB. The moving unit MP may be disposed below the gas spray unit 200 and the gas exhaust unit 300. The substrate SUB may be disposed on the moving unit MP, and the moving unit MP may linearly reciprocate inside the chamber 100. In one embodiment, the moving unit MP may move in a first direction DR1 or a second direction DR2 crossing the first direction DR1. In an embodiment, the moving unit MP may move in the first direction DR1, the second direction DR2 or a third direction DR3 crossing the first direction DR1 and the second direction DR2. In an embodiment, the moving unit MP may include a plate on which the substrate SUB is placed during a time when a process is performed, an electric motor, and a linear motor actuator between the electric motor and the plate. The linear motor actuator may convert the rotary motion of the electric motor to linear motion for moving the plate.

In the drawing, the first direction DR1 and the second direction DR2 cross each other as horizontal directions, e.g., parallel to an upper surface of an upper plate 380 or parallel to a linear motion direction of the moving unit MP. For example, the first direction DR1 and the second direction DR2 may be orthogonal to each other. The third direction DR3 crosses the first direction DR1 and the second direction DR2, and may be, for example, a vertical direction orthogonal to the first direction DR1 and the second direction DR2. In the present disclosure, a direction indicated by arrows of the first direction DR1 to the third direction DR3 may be referred to as one side, and an opposite direction thereof may be referred to as the other side.

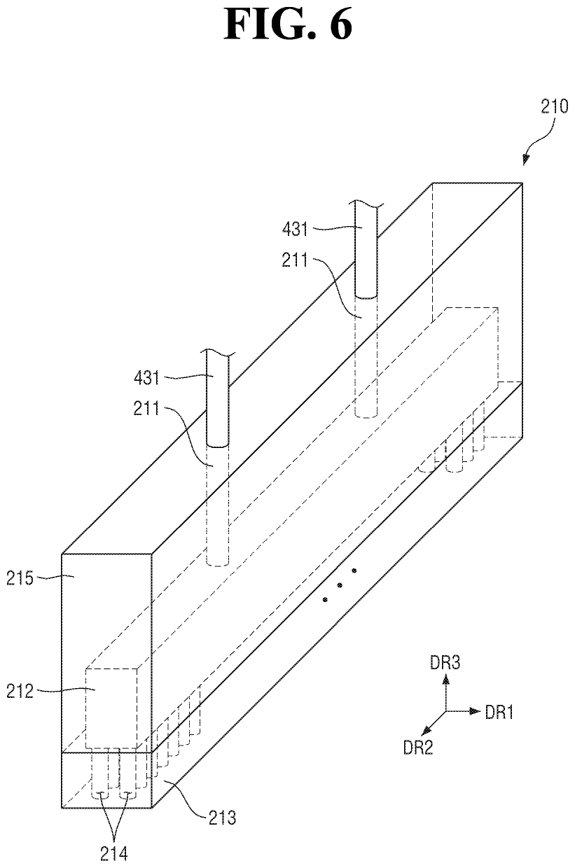

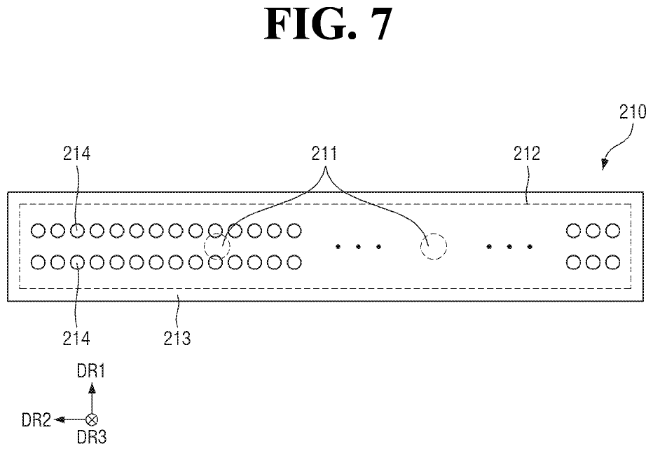

FIG. 5 is a schematic cross-sectional view illustrating a gas spray unit taken along line I-I′ of FIG. 2. FIG. 6 is a perspective view illustrating a first spray portion according to one embodiment. FIG. 7 is a bottom view illustrating a first spray portion according to one embodiment.

Referring to FIGS. 5 to 7, the gas spray unit 200 may include first to fifth spray portions 210, 220, 230, 240 and 250 spaced apart from one another along the first direction DR1. In one embodiment, the first to fifth spray portions 210, 220, 230, 240 and 250 may be arranged in due order. That is, the second spray portion 220 may be disposed between the first spray portion 210 and the third spray portion 230, and the fourth spray portion 240 may be disposed between the third spray portion 230 and the fifth spray portion 250.

In some embodiments, the spray portions 210, 220, 230, 240 and 250 of the gas spray unit 200 may be alternately disposed in accordance with the type of the gas that is sprayed. For example, the first spray portion 210, the third spray portion 230 and the fifth spray portion 250 may spray reaction gas, and the second spray portion 220 and the fourth spray portion 240 may spray source gas. In an embodiment, the first spray portion 210, the third spray portion 230 and the fifth spray portion 250 may spray source gas, and the second spray portion 220 and the fourth spray portion 240 may spray reaction gas. In the present disclosure, the case that the first spray portion 210, the third spray portion 230 and the fifth spray portion 250 spray the reaction gas and the second spray portion 220 and the fourth spray portion 240 spray the source gas will be described by way of example.

The first spray portion 210 may spray the reaction gas. For example, the first spray portion 210 may spray the first gas G1 or the third gas G3 as the first inflow gas IG1. The first spray portion 210 may include a first supply path 211, a first accommodator 212, a first plasma generator 213, a first nozzle 214 and a first body 215.

The first supply path 211 may serve as a path for the first inflow gas IG1 flowing from the first supply pipe 431 to move to the first accommodator 212. The first supply path 211 may be directly communicated with the first supply pipe 431 without a physical boundary. The first supply path 211 may be extended in the third direction DR3 to pass through at least a portion of the first body 215 in a thickness direction. In the drawing, two first supply paths 211 are illustrated, but the present disclosure is not limited thereto. In some embodiments, the first supply path 211 may be smaller or greater than two.

The first accommodator 212 may serve as a space in which the first inflow gas IG1 may be accommodated before being sprayed through the first nozzle 214. The first accommodator 212 may be extended in the second direction DR2 and positioned on the first plasma generator 213. A length of the first accommodator 212 in the first direction DR1 and the second direction DR2 may be shorter than that of the first body 215 in the first direction DR1 and the second direction DR2.

The first plasma generator 213 may spray the first inflow gas IG1 transferred from the first accommodator 212 onto the substrate SUB. The first plasma generator 213 may allow the first inflow gas IG1 passing therethrough to be selectively in a plasma state. For example, when the first inflow gas IG1 is allowed to be in a plasma state, the first plasma generator 213 may operate to allow the first inflow gas IG1 passing therethrough to be in a plasma state. Alternatively, when there is no need to form the first inflow gas IG1 into a plasma state, the first plasma generator 213 may not operate and the first inflow gas IG1 may simply pass through the first plasma generator 213. The first plasma generator 213 may include or may be a plasma generation electrode used in a deposition process.

The first plasma generator 213 may be positioned below the first body 215. A length of the plasma generator 213 in the first direction DR1 and the second direction DR2 may be the same as that of the first body 215 in the first direction DR1 and the second direction DR2. The first plasma generator 213 may surround a plurality of first nozzles 214.

The first nozzle 214 may serve as a path that allows the first inflow gas IG1 to move by passing through the first plasma generator 213. For example, the first nozzle 214 may spray the first inflow gas IG1 onto the substrate SUB. The first nozzle 214 may be directly communicated with the first accommodator 212. The first nozzle 214 may pass through the first plasma generator 213 in the third direction DR3. The first nozzle 214 may be surrounded by the first plasma generator 213.

The first nozzle 214 may be provided as a plurality of first nozzles 214. The plurality of first nozzles 214 are illustrated as being disposed side by side in two lines spaced apart from each other in the first direction DR1. Each of the two lines may extend in the second direction. In one embodiment, the plurality of first nozzles 214 may be arranged on the two lines in a zigzag manner so that no first nozzles 214 do not overlap when viewed in the first direction DR1. The present disclosure, however, is not limited thereto. In some embodiments, the plurality of first nozzles 214 may be disposed in one line or more than three lines. In an embodiment, the plurality of first nozzles 214 may be alternately disposed so as not to overlap when viewed in the first direction DR1.

The first body 215 may be disposed on the first plasma generator 213. For example, the first body 215 may be connected to the first plasma generator 213. The first body 215 may surround the first supply path 211 and the first accommodator 212. The first body 215 may have a bar shape extended in the second direction DR2.

The second spray portion 220 may spray the source gas. For example, the second spray portion 220 may spray the second gas G2 or the fourth gas G4 as the second inflow gas IG2. The second spray portion 220 may include a second supply path 221, a second accommodator 222, a second plasma generator 223, a second nozzle 224 and a second body 225.

In one embodiment, the second supply path 221, the second accommodator 222, the second plasma generator 223, the second nozzle 224 and the second body 225 of the second spray portion 220 may be similar to the first supply path 211, the first accommodator 212, the first plasma generator 213, the first nozzle 214 and the first body 215 of the first spray portion 210, respectively. However, there is a difference in that the first spray portion 210 may spray the reaction gas as the first inflow gas IG1 whereas the second spray portion 220 may spray the source gas as the second inflow gas IG2. Therefore, a detailed description of the second spray portion 220 will be omitted.

The third spray portion 230 may include a third supply path 231, a third accommodator 232, a third plasma generator 233, a third nozzle 234 and a third body 235.

The fourth spray portion 240 may include a fourth supply path 241, a fourth accommodator 242, a fourth plasma generator 243, a fourth nozzle 244 and a fourth body 245.

The fifth spray portion 250 may include a fifth supply path 251, a fifth accommodator 252, a fifth plasma generator 253, a fifth nozzle 254 and a fifth body 255.

In one embodiment, the third spray portion 230 and the fifth spray portion 250 may be the same as the first spray portion 210, and the fourth spray portion 240 may be the same as the second spray portion 220. Therefore, a detailed description of the third spray portion 230 to the fifth spray portion 250 will be omitted.

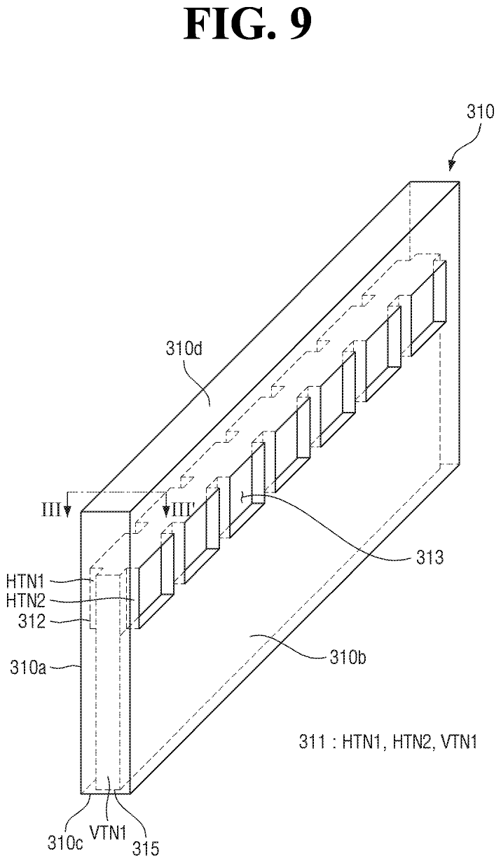

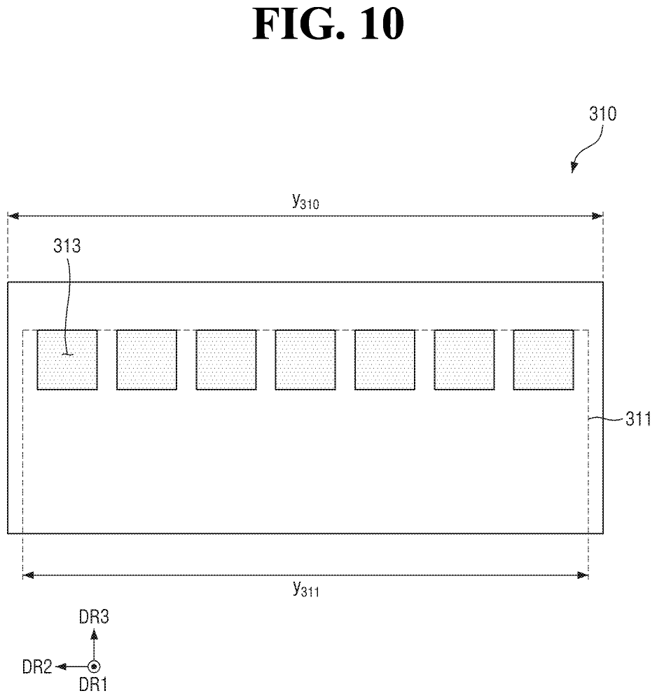

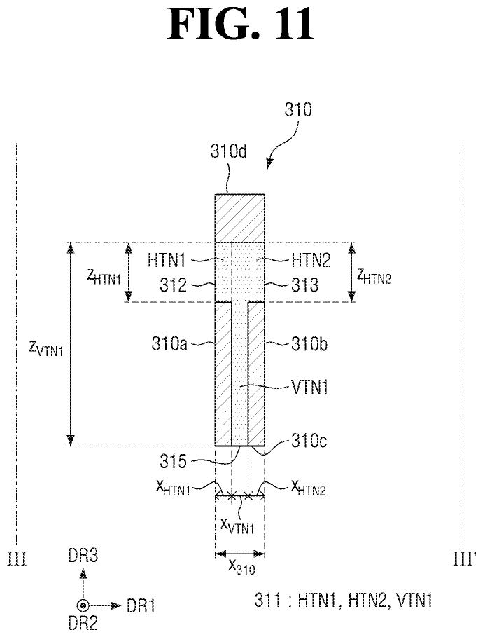

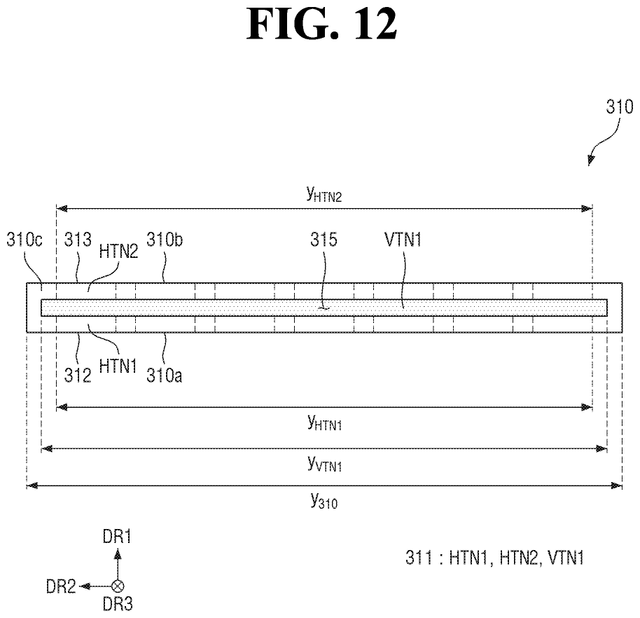

FIG. 8 is a schematic cross-sectional view illustrating a gas exhaust unit taken along line II-II′ of FIG. 2.f 431 FIG. 9 is a perspective view illustrating a first partition according to one embodiment. FIG. 10 is a side view illustrating a first partition according to one embodiment. FIG. 11 is a cross-sectional view taken along line III-III′ of FIG. 9. FIG. 12 is a bottom view illustrating a first partition according to one embodiment.

Referring to FIGS. 8 to 12, the gas exhaust unit 300 may include first to fourth partitions 310, 320, 330 and 340, first and second sidewalls 350 and 360, a main exhaust path 370 and an upper plate 380.

The first sidewall 350, the first to fourth partitions 310, 320, 330 and 340 and the second sidewall 360 may be spaced apart from one another along the first direction DR1. In one embodiment, the first sidewall 350, the first to fourth partitions 310, 320, 330 and 340 and the second sidewall 360 may be arranged in due order. That is, the first partition 310 may be disposed between the first sidewall 350 and the second partition 320, the second partition 320 may be disposed between the first partition 310 and the third partition 330, the third partition 330 may be disposed between the second partition 320 and the fourth partition 340, and the fourth partition 340 may be disposed between the third partition 330 and the second sidewall 360.

The first to fourth partitions 310, 320, 330 and 340 may have a rectangular parallelepiped shape. The first to fourth partitions 310, 320, 330 and 340 may be disposed below the upper plate 380. The first partition 310 may include a first horizontal opening 312, a second horizontal opening 313, a first vertical opening 315 and a first sub exhaust path 311. The second partition 320 may include a third horizontal opening 322, a fourth horizontal opening 323, a second vertical opening 325 and a second sub exhaust path 321. The third partition 330 may include a fifth horizontal opening 332, a sixth horizontal opening 333, a third vertical opening 335 and a third sub exhaust path 331. The fourth partition 340 may include a seventh horizontal opening 342, an eighth horizontal opening 343, a fourth vertical opening 345 and a fourth sub exhaust path 341. The second partition 320 to the fourth partition 340 may have the same configuration as that of the first partition 310. Therefore, a detailed description of the configuration of the second partition 320 to the fourth partition 340 will be omitted, and the following description will be based on the configuration of the first partition 310.

The first partition 310 may include a first horizontal opening 312 formed at a left side 310a, a second horizontal opening 313 formed at a right side 310b, and a first vertical opening 315 formed at a lower surface 310c. The first partition 310 may include an empty inner space surrounded by an outer surface of the first partition 310. The empty inner space may be a first sub exhaust path 311 that connects the first horizontal opening 312, the second horizontal opening 313, and the first vertical opening 315 with each other.

The first sub exhaust path 311 may include a first vertical tunnel VTN1 extended from the first vertical opening 315 to one point inside the first partition 310 along the second direction DR2, a first horizontal tunnel HTN1 connecting the first horizontal opening 312 to the first vertical tunnel VTN1, and a second horizontal tunnel HTN2 connecting the second horizontal opening 313 to the first vertical tunnel VTN1.

The first vertical tunnel VTN1 may pass through the lower surface 310c of the first partition 310 through the first vertical opening 315. For example, the first vertical tunnel VTN1 may pass through the lower surface 310c of the first partition 310 and at least a portion of the inside of the first partition 310 but may not pass through an upper surface 310d of the first partition 310. The first vertical tunnel VTN1 may be disposed at the center of the first partition 310 in the second direction DR2.

The first horizontal tunnel HTN1 may pass through the left side 310a of the first partition 310 through the first horizontal opening 312. For example, the first horizontal tunnel HTN1 may pass through the left side 310a of the first partition 310 and at least a portion of the inside of the first partition 310, and may be directly communicated with the first vertical tunnel VTN1 without a physical boundary.

The second horizontal tunnel HTN2 may pass through the right side 310b of the first partition 310 through the second horizontal opening 313. For example, the second horizontal tunnel HTN2 may pass through the right side 310b of the first partition 310 and at least a portion of the inside of the first partition 310, and may be directly communicated with the first vertical tunnel VTN1 without a physical boundary.

The first horizontal opening 312 and the second horizontal opening 313 may include a plurality of openings disposed side by side in the second direction DR2. The first horizontal tunnel HTN1 and the second horizontal tunnel HTN2 may include a plurality of tunnels disposed side by side in the second direction DR2 to connect the first horizontal opening 312 and the second horizontal opening 313, which include the plurality of openings, with each other. Each of the first horizontal opening 312 and the second horizontal opening 313 is shown as including seven openings and each of the first horizontal tunnel HTN1 and the second horizontal tunnel HTN2 is shown as including seven tunnels, but the present disclosure is not limited thereto.

A length x_{VTN1} of the first vertical tunnel VTN1 in the first direction DR1 may be longer than or equal to each of a length x_{HTN1} of the first horizontal tunnel HTN1 in the first direction DR1 and a length x_{HTN2} of the second horizontal tunnel HTN2 in the first direction DR1. For example, the length x_{VTN1} of the first vertical tunnel VTN1 in the first direction DR1 may be one time or two times each of the length x_{HTN1} of the first horizontal tunnel HTN1 in the first direction DR1 and the length x_{HTN2} of the second horizontal tunnel HTN2 in the first direction DR1. When the length x_{VTN1} of the first vertical tunnel VTN1 in the first direction DR1 is one time or more each of the length x_{HTN1} of the first horizontal tunnel HTN1 in the first direction DR1 and the length x_{HTN2} of the second horizontal tunnel HTN2 in the first direction DR1, gas may be actively exhausted. When the length x_{VTN1} of the first vertical tunnel VTN1 in the first direction DR1 is two times or less each of the length x_{HTN1} of the first horizontal tunnel HTN1 in the first direction DR1 and the length x_{HTN2} of the second horizontal tunnel HTN2 in the first direction DR1, durability of the first partition 310 may be improved.

A length y₃₁₁ of the first sub exhaust path 311 in the second direction DR2 and a length y_{VTN1} of the first vertical tunnel VTN1 in the second direction DR2 may be smaller than a length y₃₁₀ of the first partition 310 in the second direction DR2. The length y_{VTN1} of the first vertical tunnel VTN1 in the second direction DR2 may be longer than a length y_{HTN1} of the first horizontal tunnel HTN1 in the second direction DR2 and a length y_{HTN2} of the second horizontal tunnel HTN2 in the second direction DR2. The length y_{VTN1} of the first vertical tunnel VTN1 in the second direction DR2 may be longer than the length y_{HTN1} of the first horizontal tunnel HTN1 in the second direction DR2 and the length y_{HTN2} of the second horizontal tunnel HTN2 in the second direction DR2 so that exhaust capability of the first sub exhaust path 311 may be improved.

One ends of the first vertical tunnel VTN1, the first horizontal tunnel HTN1 and the second horizontal tunnel HTN2 in the third direction DR3 may be matched with one another. For example, the first horizontal tunnel HTN1 and the second horizontal tunnel HTN2 may be positioned at the same level along the third direction DR3, and may be positioned to be adjacent to an upper portion of the first vertical tunnel VTN1.

A length z_{VTN1} of the first vertical tunnel VTN1 in the third direction DR3 may be longer than each of a length z_{HTN1} of the first horizontal tunnel HTN1 in the third direction DR3 and a length z_{HTN2} of the second horizontal tunnel HTN2 in the third direction DR3. In one embodiment, the length z_{VTN1} of the first vertical tunnel VTN1 in the third direction DR3 may be three to five times the length z_{HTN1} of the first horizontal tunnel HTN1 in the third direction DR3 and the length z_{HTN2} of the second horizontal tunnel HTN2 in the third direction DR3.

The first horizontal tunnel HTN1 and the second horizontal tunnel HTN2 are positioned to be adjacent to the upper portion of the first vertical tunnel VTN1 and the length z_{HTN1} of the first horizontal tunnel HTN1 in the third direction DR3 and the length z_{HTN2} of the second horizontal tunnel HTN2 in the third direction DR3 may be shorter than the length z_{VTN1} of the first vertical tunnel VTN1 in the third direction DR3, whereby exhaust gas or emitted gas may be prevented from flowing backward to a lower portion of the first partition 310.

The first sidewall 350 may be positioned at the other edge of the gas exhaust unit 300 in the first direction DR1, that is, on the left edge in the drawing. The first sidewall 350 may include a ninth horizontal opening 352, a fifth vertical opening 355 and a fifth sub exhaust path 351.

The ninth horizontal opening 352 of the first sidewall 350 may be the same as the second horizontal opening 313 of the first partition 310, and the fifth vertical opening 355 of the first sidewall 350 may be the same as the first vertical opening 315 of the first partition 310. The fifth sub exhaust path 351 of the first sidewall 350 is similar to the first sub exhaust path 311 of the first partition 310, but is different from the first partition 310 only in that it does not include a left horizontal tunnel.

That is, the first sidewall 350 is different from the first partition 310 only in that it does not include a left opening and a left horizontal tunnel in the drawing. Therefore, a detailed description of the first sidewall 350 will be omitted.

The second sidewall 360 may be positioned at one edge of the gas exhaust unit 300 in the first direction DR1, that is, at a right edge in the drawing. The second sidewall 360 may include a tenth horizontal opening 362, a sixth vertical opening 365 and a sixth sub exhaust path 361.

The tenth horizontal opening 362 of the second sidewall 360 may be the same as the first horizontal opening 312 of the first partition 310, and the sixth vertical opening 365 of the second sidewall 360 may be the same as the first vertical opening 315 of the first partition 310. The sixth sub exhaust path 361 of the second sidewall 360 is similar to the first sub exhaust path 311 of the first partition 310, but is different from the first partition 310 only in that it does not include a right horizontal tunnel.

That is, the second sidewall 360 is different from the first partition 310 only in that it does not include a right opening and a right horizontal tunnel in the drawing. Therefore, a detailed description of the second sidewall 360 will be omitted.

The main exhaust path 370 may exhaust the gas sprayed from the gas spray unit 200. The main exhaust path 370 may be directly communicated with the emission pipe 520 of the gas emission unit 500 without a physical boundary.

The main exhaust path 370 may include first to fifth main exhaust paths 371, 372, 373, 374 and 375. The main exhaust path 370 may be positioned among the first sidewall 350, the first to fourth partitions 310, 320, 330 and 340 and the second sidewall 360. For example, the first main exhaust path 371 may be positioned between the first sidewall 350 and the first partition 310, the second main exhaust path 372 may be positioned between the first partition 310 and the second partition 320, the third main exhaust path 373 may be positioned between the second partition 320 and the third partition 330, the fourth main exhaust path 374 may be positioned between the third partition 330 and the fourth partition 340, and the fifth main exhaust path 375 may be positioned between the fourth partition 340 and the second sidewall 360.

The upper plate 380 may be disposed above the first sidewall 350, the first to fourth partitions 310, 320, 330 and 340 and the second sidewall 360. The upper plate 380 may be directly in contact with the upper surfaces of the first sidewall 350, the first to fourth partitions 310, 320, 330 and 340 and the second sidewall 360 and coupled to one another. The upper plate 380 may be penetrated in the third direction DR3 by the supply pipe 430 and the emission pipe 520.

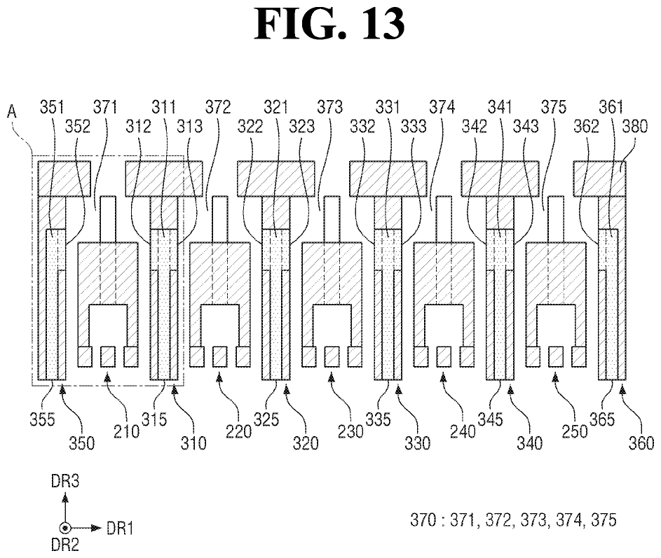

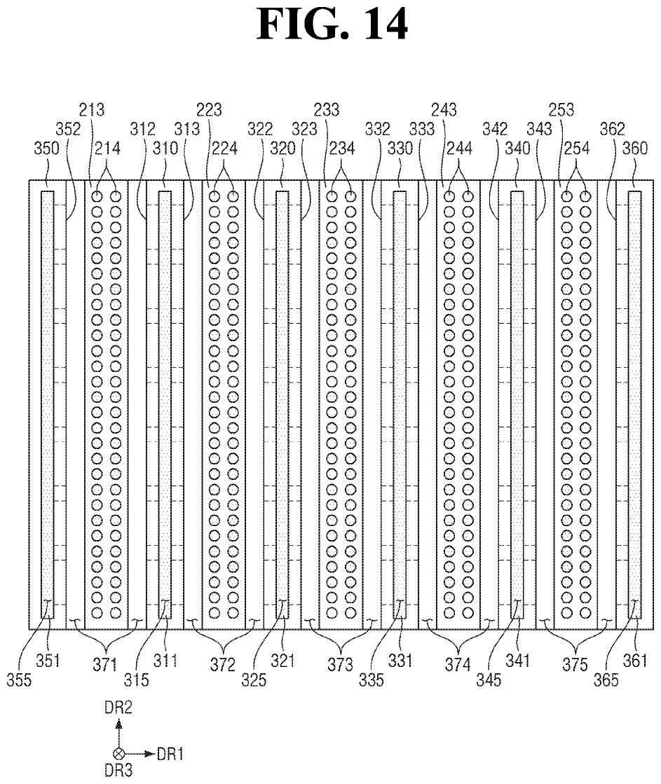

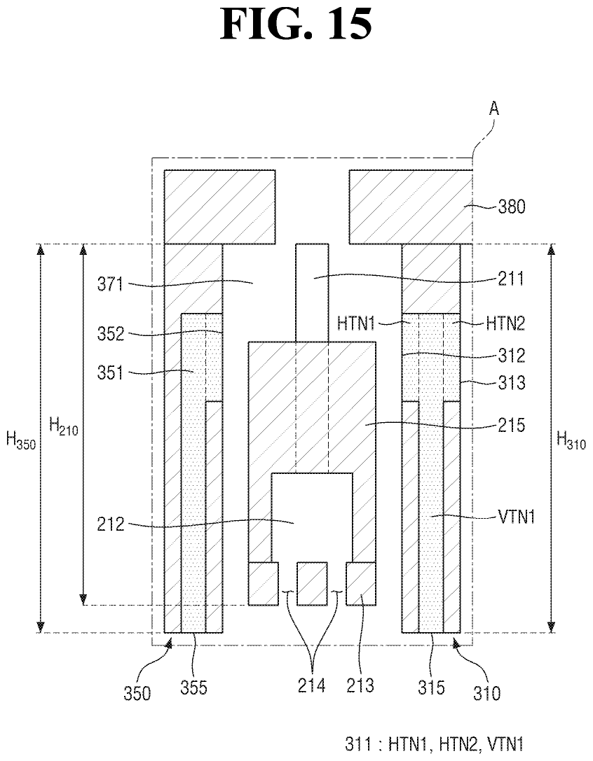

FIG. 13 is a schematic cross-sectional view illustrating a gas spray unit and a gas exhaust unit according to one embodiment. FIG. 14 is a bottom view illustrating a gas spray unit and a gas exhaust unit according to one embodiment. FIG. 15 is an enlarged view illustrating a portion ‘A’ of FIG. 13.

Referring to FIGS. 13 to 15, a plurality of partitions and a plurality of sidewalls may be disposed alternately with a plurality of spray portions. Each of the plurality of spray portions may be disposed in the main exhaust path 370. For example, the first spray portion 210 may be disposed in the first main exhaust path 371, the second spray portion 220 may be disposed in the second main exhaust path 372, the third spray portion 230 may be disposed in the third main exhaust path 373, the fourth spray portion 240 may be disposed in the fourth main exhaust path 374, and the fifth spray portion 250 may be disposed in the fifth main exhaust path 375.

A length H₂₁₀ of the first spray portion 210 in the third direction DR2, that is, a height H₂₁₀ of the first spray portion 210 may be shorter than each of a height H₃₅₀ of the first sidewall 350 and a height H₃₁₀ of the first partition 310. For example, one end of the first sidewall 350 and the first partition 310, that is, the other side end thereof in the third direction DR3 may protrude beyond one end of the first spray portion 210, that is, the other side end of the first spray portion in the third direction DR3. Like the first spray portion 210, the height of the second to fifth spray portions 220, 230, 240 and 250 may be also shorter than the height of the second to fourth partitions 320, 330 and 340 and the second sidewall 360, and one end of the second to fourth partitions 320, 330 and 340 and the second sidewall 360 may protrude beyond one end of the second to fifth spray portions 220, 230, 240 and 250. In this way, the end of the partition may protrude beyond the end of the spray portion so that the gases sprayed from the adjacent spray portions may be prevented from being mixed with each other and deposited on the substrate SUB.

The horizontal openings included in the plurality of partitions and the plurality of sidewalls may be positioned at a higher level in the third direction DR3 than the nozzles included in the plurality of spray portions. For example, the first horizontal opening 312 and the second horizontal opening 313 may be positioned at a higher level in the third direction DR3 than the first nozzle 214 and the second nozzle 224.

The vertical openings included in the plurality of partitions and the plurality of sidewalls may be positioned at a lower level in the third direction DR3 than the nozzles included in the plurality of spray portions. For example, the first vertical opening 315 may be positioned at a lower level in the third direction DR3 than the first nozzle 214 and the second nozzle 224.

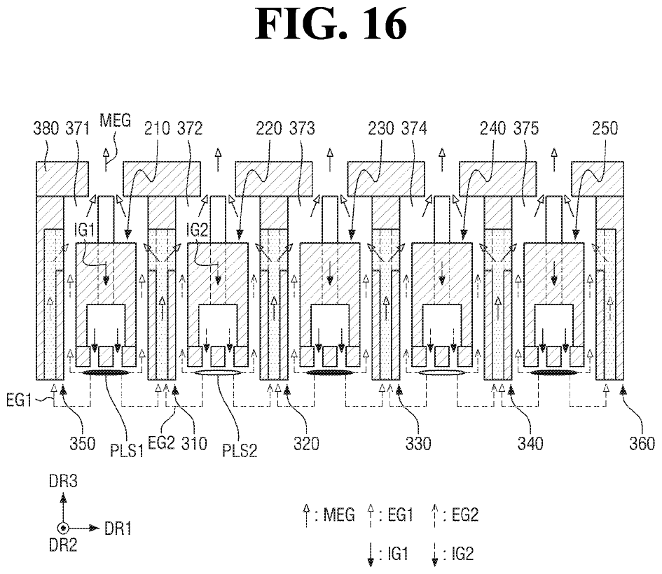

FIG. 16 is a cross-sectional view illustrating an operation state of an apparatus for manufacturing a display device according to one embodiment.

Referring to FIG. 16, the first inflow gas IG1 may flow into the first accommodator 212, the third accommodator 232 and the fifth accommodator 252 through the first supply path 211, the third supply path 231 and the fifth supply path 251, respectively. The second inflow gas IG2 may flow into the second accommodator 222 and the fourth accommodator 242 through the second supply path 221 and the fourth supply path 241, respectively.

The first inflow gas IG1 may pass through the first plasma generator 213, the third plasma generator 233 and the fifth plasma generator 253 through the first nozzle 214, the third nozzle 234 and the fifth nozzle 254, respectively. The second inflow gas IG2 may pass through the second plasma generator 223 and the fourth plasma generator 243 through the second nozzle 224 and the fourth nozzle 244, respectively.

The first inflow gas IG1 and the second inflow gas IG2 may be converted into an ionized state or may be activated into radicals by the plasma generation electrode while passing through the respective plasma generators 213, 223, 233, 243 and 253. For example, the first inflow gas IG1 and the second inflow gas IG2 may be converted into a state of a first plasma PLS1 and a state of a second plasma PLS2, respectively. A portion of the first plasma PLS1 and the second plasma PLS2 may be adsorbed onto the substrate SUB, and the remaining portion thereof may be emitted through the main exhaust path 370 or the sub exhaust paths 311, 321, 331, 341, 351 and 361.

The first exhaust gas EG1 may be emitted through the first main exhaust path 371, the third main exhaust path 373 and the fifth main exhaust path 375, and the second exhaust gas EG2 may be emitted through the second main exhaust path 372 and the fourth main exhaust path 374. The first exhaust gas EG1 may include a first inflow gas IG1 that is not ionized or is not activated into radicals and a first plasma PLS1 that is ionized, and the second exhaust gas EG2 may include a second inflow gas IG2 that is not ionized and a second plasma PLS2 that is ionized.

The first partition 310 may serve to block the first plasma PLS1 sprayed from the first spray portion 210 and the second plasma PLS2 sprayed from the second spray portion 220 from being mixed with each other, thereby being sprayed onto the substrate SUB. The second partition 320 may serve to block the second plasma PLS2 sprayed from the second spray portion 220 and the first plasma PLS1 sprayed from the third spray portion 230 from being mixed with each other, thereby being sprayed onto the substrate SUB. The third partition 330 may serve to block the first plasma PLS1 sprayed from the third spray portion 230 and the second plasma PLS2 sprayed from the fourth spray portion 240 from being mixed with each other, thereby being sprayed onto the substrate SUB. The fourth partition 340 may serve to block the second plasma PLS2 sprayed from the fourth spray portion 240 and the first plasma PLS1 sprayed from the fifth spray portion 250 from being mixed with each other, thereby being sprayed onto the substrate SUB.

The first to sixth sub exhaust paths 311, 321, 331, 341, 351 and 361 may provide an additional exhaust space so that residual gases not adsorbed on the substrate SUB may be smoothly emitted to the outside. The first to tenth horizontal openings 312, 313, 322, 323, 332, 333, 342, 343, 352 and 362 and the first to sixth vertical openings 315, 325, 335, 345, 355 and 365 may serve as paths to actively exhaust gases by connecting the first to sixth sub exhaust paths 311, 321, 331, 341, 351 and 361 with the main exhaust path 370, respectively.

In this embodiment, the first exhaust gas EG1 may move through the first to sixth sub exhaust paths 311, 321, 331, 341, 351 and 361, and the second emission gas EG2 may move through the first to fourth sub exhaust paths 311, 321, 331 and 341. For example, a mixed emission gas MEG in which the first exhaust gas EG1 and the second exhaust gas EG2 are mixed with each other may move through the first to fourth sub exhaust paths 311, 321, 331 and 341.

The mixed emission gas MEG passing through the first to fourth sub exhaust paths 311, 321, 331 and 341 may move to the gas emission unit 500 via the main exhaust path 370. The first exhaust gas EG1 passing through the fifth and sixth sub exhaust paths 351 and 361 may move to the gas emission unit 500 together with the mixed emission gas MEG through the first and fifth main exhaust paths 371 and 375.

In this way, the apparatus 1 for manufacturing a display device according to one embodiment may include the sub exhaust paths and the openings on the sidewalls and the partitions to improve exhaust performance, thereby minimizing a mixture phenomenon of the residual gases. Therefore, the display device manufactured by the apparatus 1 for manufacturing a display device according to one embodiment may have improved film forming uniformity.

Hereinafter, the apparatus for manufacturing a display device according to one embodiment will be described. In the following embodiments, the same elements as those in the previous embodiment will be referred to as the same reference numerals, and their redundant description will be omitted or simplified and the following description will be based on differences.

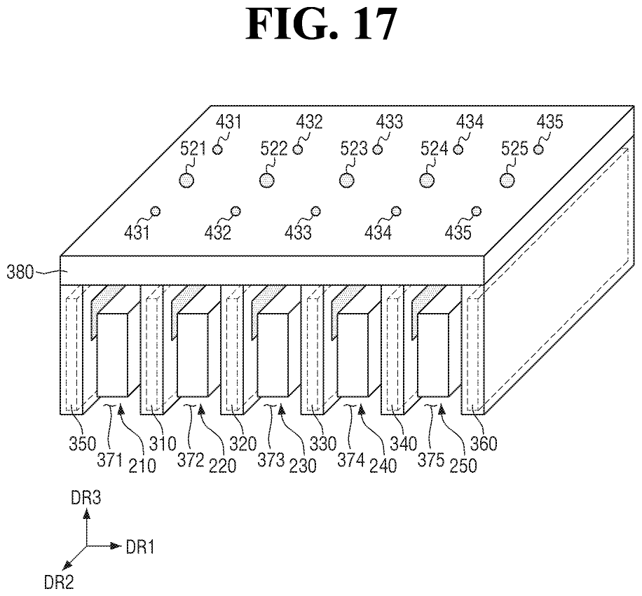

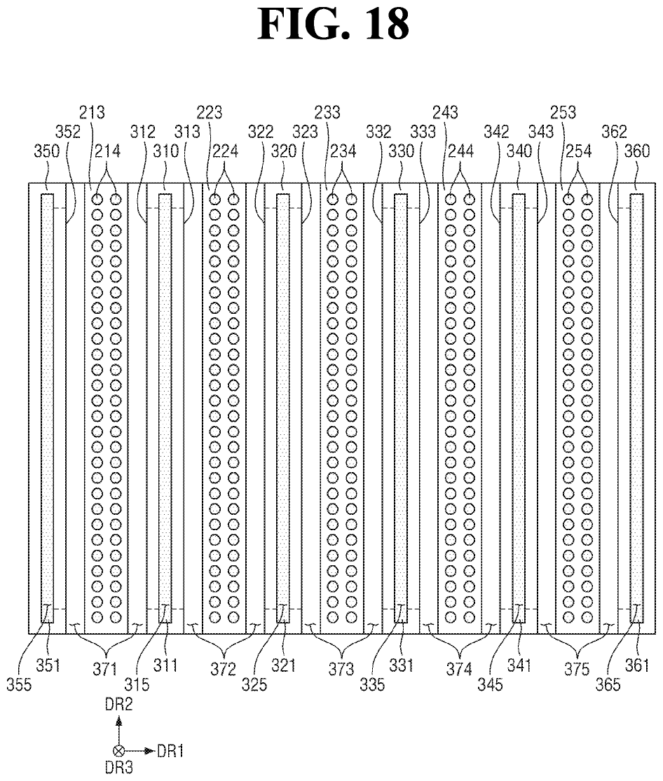

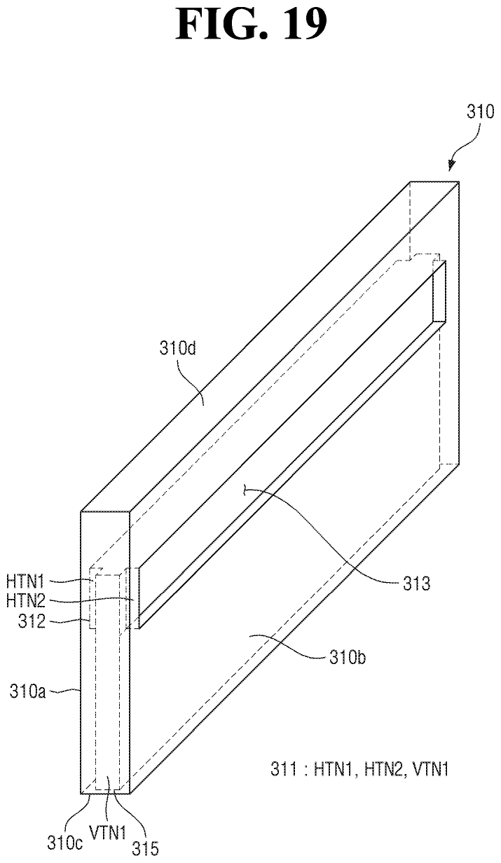

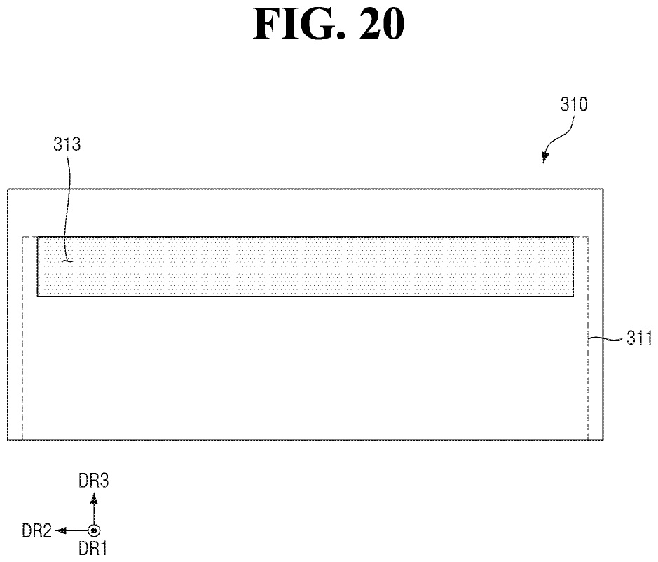

FIG. 17 is a schematic perspective view illustrating a gas spray unit and a gas exhaust unit according to an embodiment. FIG. 18 is a bottom view illustrating a gas spray unit and a gas exhaust unit according to an embodiment. FIG. 19 is a perspective view illustrating a first partition according to an embodiment. FIG. 20 is a side view illustrating a first partition according to an embodiment.

Referring to FIGS. 17 to 20, an apparatus 1 for manufacturing a display device according to an embodiment is different from the apparatus 1 of a display device according to one embodiment described with reference to FIG. 2 in that openings formed on sidewalls and partitions may be formed as one opening extended along the second direction DR2 and horizontal tunnels formed on the sidewalls and the partitions may be formed as one horizontal tunnel along the second direction DR2.

In an embodiment, the first to tenth horizontal openings 312, 313, 322, 323, 332, 333, 342, 343, 352 and 362 are the same as one another. In an embodiment, the first to tenth horizontal tunnels HTN1, HTN2, HTN3, HTN4, HTN5, HTN6, HTN7, HTN8, HTN9 and HTN10 are the same as one another. Therefore, the first horizontal opening 312, the second horizontal opening 313, the first horizontal tunnel HTN1 and the second horizontal tunnel HTN2 will be described hereinafter by way of example.

The first horizontal opening 312 and the second horizontal opening 313, which are included in the first partition 310, may include one opening having a shape extended in the second direction DR2. Therefore, the first horizontal tunnel HTN1 and the second horizontal tunnel HTN2 may include one tunnel having a shape extended in the second direction DR2 to connect the first horizontal opening 312 with the second horizontal opening 313.

In an embodiment, each of the first and second horizontal openings 312 and 313 and the first and second horizontal tunnels HTN1 and HTN2 may have a wider opening area and a larger tunnel volume than the case that a plurality of openings and a plurality of tunnels are provided. Therefore, exhaust gas moving through the first and second horizontal openings 312 and 313 and the first and second horizontal tunnels HTN1 and HTN2 may be actively emitted, whereby exhaust performance of the apparatus 1 for manufacturing a display device may be improved, and thus film forming uniformity of the display device manufactured using the same may be improved.

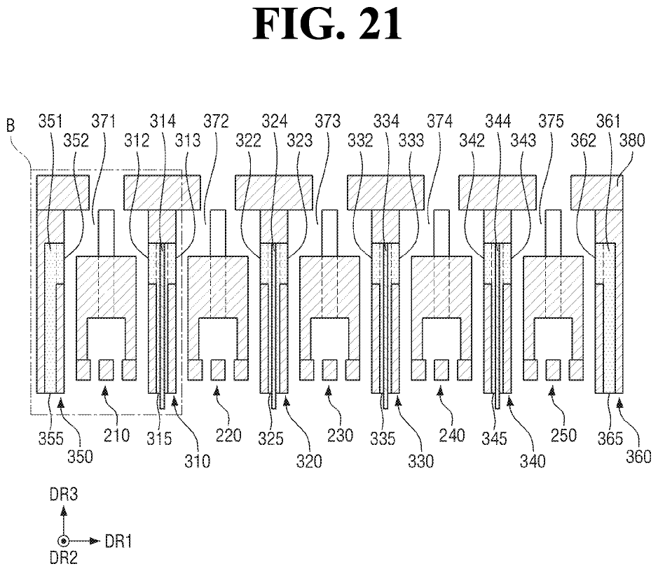

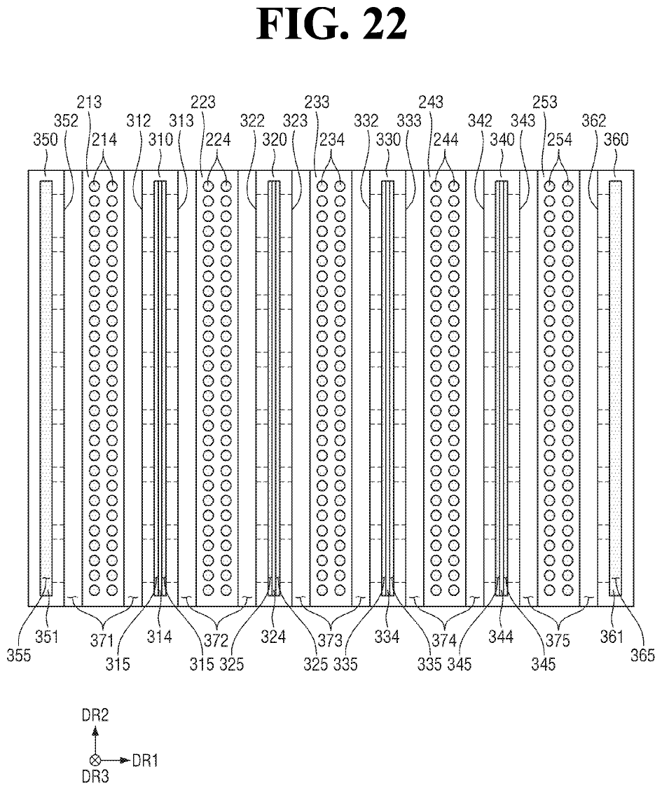

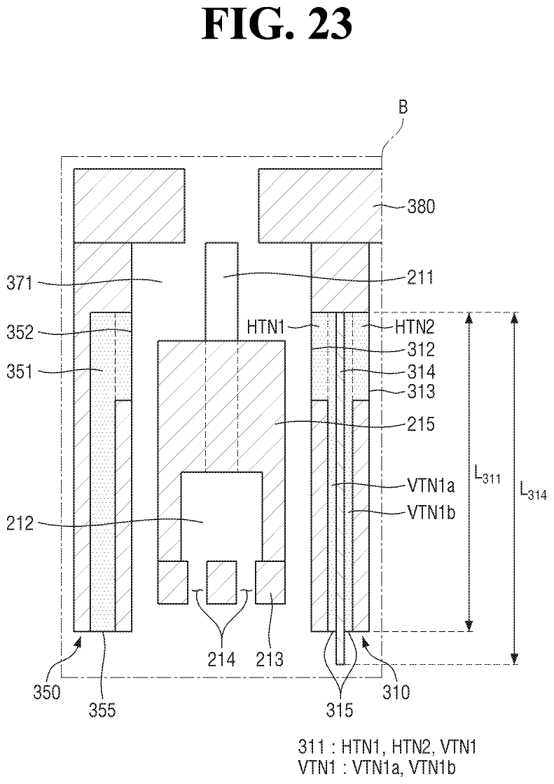

FIG. 21 is a schematic cross-sectional view illustrating a gas spray unit and a gas exhaust unit according to an embodiment. FIG. 22 is a bottom view illustrating a gas spray unit and a gas exhaust unit according to an embodiment. FIG. 23 is an enlarged view illustrating a portion ‘B’ of FIG. 21.

Referring to FIGS. 21 to 23, the apparatus 1 for manufacturing a display device according to an embodiment is different from the apparatus 1 for manufacturing a display device according to one embodiment described with reference to FIG. 2 in that the first to fourth partitions 310, 320, 330 and 340 may further include first to fourth sub partitions 314, 324, 334 and 344.

In an embodiment, the first to fourth partitions 310, 320, 330 and 340 may be the same as one another, and the following description will be based on the first partition 310.

In an embodiment, the first partition 310 of the apparatus 1 for manufacturing a display device may further include a first sub partition 314 in the first sub exhaust path 311. In one embodiment, each of the first sub partitions 314 may be disposed at the center of the first sub exhaust path 311 in the first direction DR1. In one embodiment, the first sub partition 314 may be a plate of a rectangular shape. The present disclosure is not limited thereto. For example, the first sub partition 314 may be a plate of various shapes.

The first vertical tunnel VTN1 of the first sub exhaust path 311 may be divided into a first sub area VTN1a and a second sub area VTN1b, which are spaced apart from each other with the first sub partition 314 interposed therebetween. The first sub partition 314 may be extended in the third direction DR3 to space or separate the first horizontal tunnel HTN1 and the second horizontal tunnel HTN2 apart from or from each other so that the first horizontal tunnel HTN1 and the second horizontal tunnel HTN2 may not be communicated with each other.

The first sub partition 314 may be formed to be longer than the first sub exhaust path 311. That is, a length L₃₁₄ of the first sub partition 314 in the third direction DR3 may be longer than a length L₃₁₁ of the first sub exhaust path 311 in the third direction DR3. In one embodiment, one end of the first sub partition 314, that is, the other end of the first sub partition 314 in the third direction DR3 may protrude beyond one end of the first sub exhaust path 311, that is, the other end of the first sub exhaust path 311 in the third direction DR3. In this way, one end of the first sub partition 314 may protrude beyond one end of the first sub exhaust path 311, so that the gas sprayed from the first spray portion 210 may be prevented from moving to the second sub area VTN1b and the gas sprayed from the second spray portion 220 may be prevented from moving to the first sub area VTN1a.

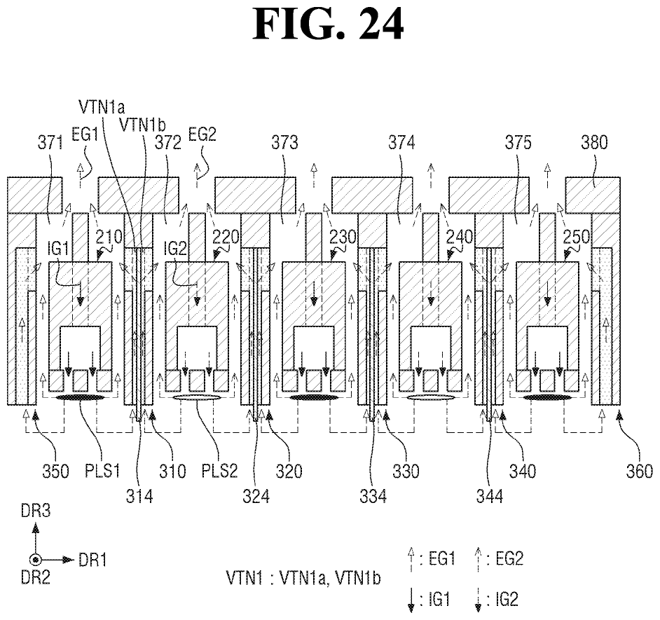

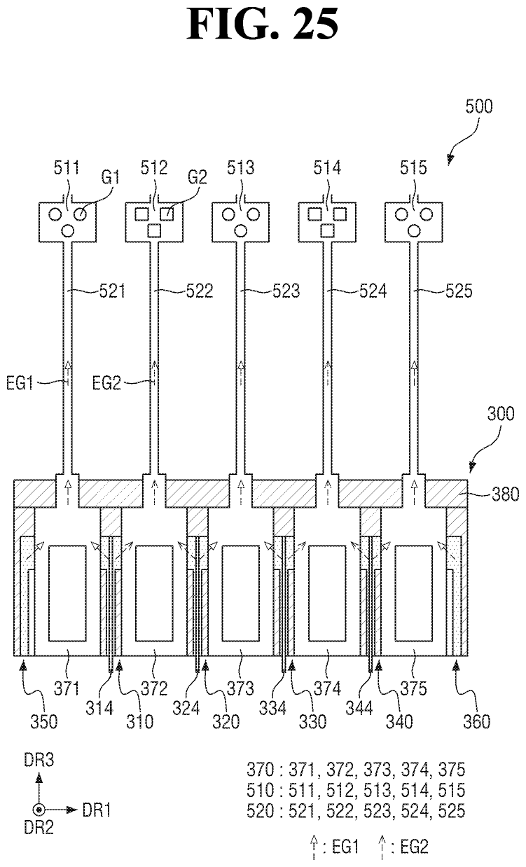

FIG. 24 is a view illustrating an operation state of an apparatus for manufacturing a display device according to an embodiment. FIG. 25 is a schematic conceptual view illustrating a gas emission unit and a gas exhaust unit according to an embodiment.

According to an embodiment, an operation state of the apparatus 1 for manufacturing a display device will be described with reference to FIGS. 24 and 25. The apparatus 1 for manufacturing a display device is different from the apparatus 1 for manufacturing a display device as described with reference to FIG. 16 in that the first emission gas EG1 and the second emission gas EG2 are emitted through separate exhaust paths and emission pipes, respectively, without being mixed with each other.

In this embodiment, the first exhaust gas EG1 may move through the first sub area VTN1a, and the second exhaust gas EG2 may move through the second sub area VTN1b. The first sub partition 314 may prevent the first exhaust gas EG1 from moving to the second sub area VTN1b, and may prevent the second exhaust gas EG2 from moving to the first sub area VTN1a. The first sub partition 314 may prevent the first emission gas EG1 and the second emission gas EG2 from being mixed with each other, thereby preventing the mixture emission gas MEG from being formed.

Likewise, the second to fourth sub partitions 324, 334 and 344 may also prevent the first exhaust gas EG1 and the second exhaust gas EG2 from being mixed with each other, thereby preventing the mixture emission gas MEG from being formed.

The first exhaust gas EG1 passing through each sub exhaust path may be emitted through the first main exhaust path 371, the third main exhaust path 373 and the fifth main exhaust path 375, and the second exhaust gas EG2 may be emitted through the second main exhaust path 372 and the fourth main exhaust path 374.

The first exhaust gas EG1 passing through each main exhaust path may be emitted to the outside through the first emission pump 511, the third emission pump 513 and the fifth emission pump 515 by passing through the first emission pipe 521, the third emission pipe 523 and the fifth emission pipe 525, respectively. The second emission gas EG2 passing through each main exhaust path may be emitted to the outside through the second emission pump 512 and the fourth emission pump 514 by passing through the second emission pipe 522 and the fourth emission pipe 524, respectively.

According to an embodiment, the apparatus 1 for manufacturing a display device includes first to fourth sub partitions 314, 324, 334 and 344 so as to emit the first exhaust gas EG1 and the second exhaust gas EG2, that is, the reaction gas and the source gas to the outside without being mixed with each other. Therefore, the reaction gas and the source gas may be prevented from causing a chemical reaction in the process of being emitted, thereby preventing explosion or combustion from occurring.

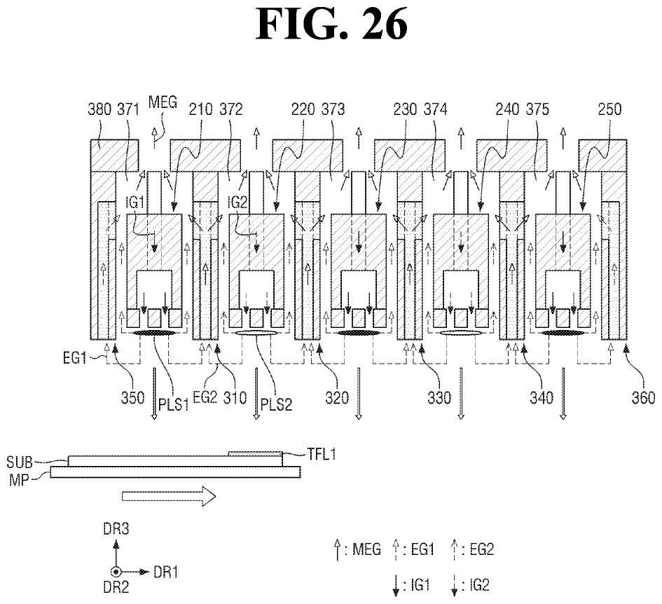

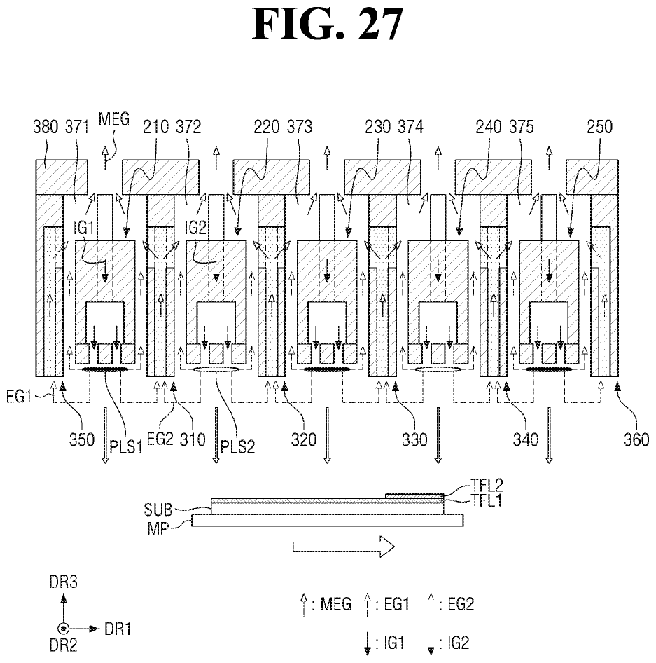

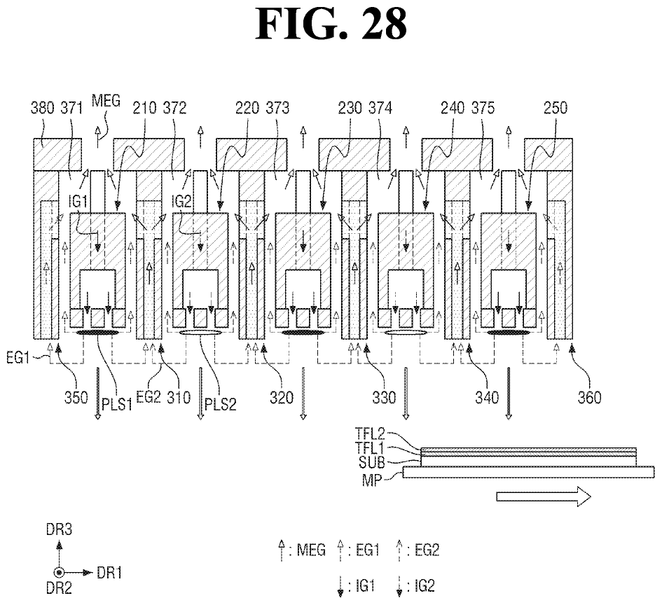

FIGS. 26 to 28 are cross-sectional views illustrating a process of an apparatus for manufacturing a display device according to the above-described embodiments.

Referring to FIGS. 26 to 28, the moving unit MP may move the substrate SUB along the first direction DR1. While the substrate SUB is moving from the lower portion of the first to fifth spray portions 210, 220, 230, 240 and 250 along the first direction DR1, the first to fifth spray portions 210, 220, 230, 240 and 250 may spray plasma-type gas onto the substrate SUB.

The first spray portion 210, the third spray portion 230 and the fifth spray portion 250 may spray the reaction gas. The second spray portion 220 and the fourth spray portion 240 may spray the source gas.

While the substrate SUB is passing two adjacent spray portions in turn while linearly reciprocating in the first direction DR1, one thin film layer may be formed.

For example, the reaction gas may be attached to the substrate SUB passing through the lower portion of the first spray portion 210. While the substrate SUB having the reaction gas attached thereto is passing through the lower portion of the second spray portion 220, the source gas may be attached to the substrate SUB. The reaction gas and the source gas, which are attached to the substrate SUB, may mutually cause a chemical reaction to form a first thin film layer TFL1.

The reaction gas may be attached onto the first thin film layer TFL1 while the substrate SUB on which the first thin film layer TFL1 is formed is passing through the lower portion of the third spray portion 230. The source gas may be attached to the first thin film layer TFL1 while the first thin film layer TFL1 to which the reaction gas is attached is passing through the lower portion of the fourth spray portion 240. The reactive gas and the source gas, which are attached onto the first thin film layer TFL1, may mutually cause a chemical reaction to form a second thin film layer TFL2.

The apparatus 1 for manufacturing a display device according to the above-described embodiments is a space division type vapor deposition apparatus, which may separate the space to spray the source gas and the reaction gas, thereby quickly stacking a large area through a continuous process of reciprocating the substrate and shortening a process time.

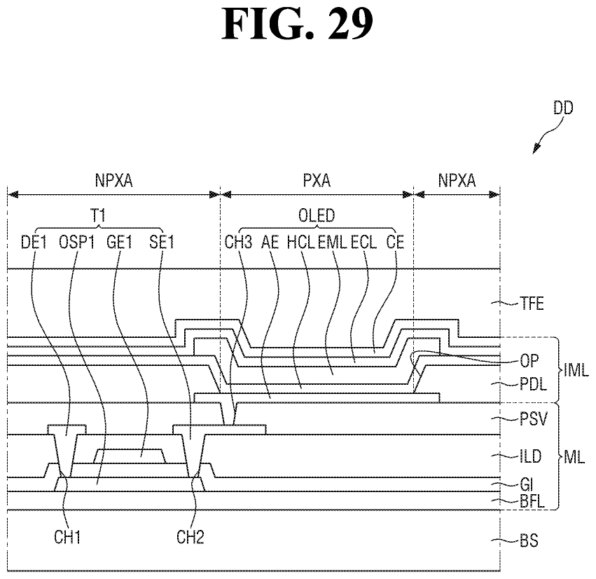

FIG. 29 is a cross-sectional view illustrating a portion of a display device manufactured by an apparatus for manufacturing the display device according to the above-described embodiments.

Referring to FIG. 29, a display device DD manufactured by the apparatus 1 for manufacturing a display device according to the above-described embodiments may include a display panel (not shown).

The display panel (not shown) may include a light emitting display panel. The light emitting display panel may be, for example, an organic light emitting display panel or a quantum dot light emitting display panel. A light emitting layer of the organic light emitting display panel may include or may be formed of an organic light emitting material. A light emitting layer of the quantum dot light emitting display panel may include or may be formed of a quantum dot and a quantum rod. This is exemplary, and the display panel (not shown) is not particularly limited in the present disclosure. In this embodiment, an organic light emitting display panel is exemplarily shown as the display panel (not shown).

The display panel (not shown) may include a base layer BS, a circuit element layer ML, a display element layer IML and a thin film encapsulation layer TFE. The circuit element layer ML, the display element layer IML and the thin film encapsulation layer TFE may be sequentially disposed on the base layer BS.

The base layer BS may include or may be a synthetic resin film. A synthetic resin layer may be formed on a working substrate used for manufacturing a display panel DP. Afterwards, a conductive layer and an insulating layer may be formed on the synthetic resin layer. When the working substrate is removed, the synthetic resin layer may correspond to the base layer BS. The synthetic resin layer may include or may be formed of a thermosetting resin. In particular, the synthetic resin layer may be a polyimide-based resin layer, and its material is not particularly limited. In addition, the base layer BS may include or may be an organic/inorganic composite material substrate or the like.

In this embodiment, the circuit element layer ML may include a buffer layer BFL, a first intermediate inorganic layer GI and a second intermediate inorganic layer ILD, which are inorganic layers, and an intermediate organic layer PSV that is an organic layer. Materials of the inorganic layer and the organic layer are not particularly limited, and in one embodiment, the buffer layer BFL may be selectively disposed/omitted.

A semiconductor pattern OSP1 of a transistor T1 may be disposed on the buffer layer BFL. The semiconductor pattern OSP1 may be selected from amorphous silicon, polysilicon or a metal oxide semiconductor.

The first intermediate inorganic layer GI may be disposed on the semiconductor pattern OSP1. A control electrode GE1 of the transistor T1 may be disposed on the first intermediate inorganic layer GI.

The second intermediate inorganic layer ILD covering the control electrode GE1 may be disposed on the first intermediate inorganic layer GI. An input electrode DE1 and an output electrode SE1 of the transistor T1 may be disposed on the second intermediate inorganic layer ILD.

The input electrode DE1 and the output electrode SE1 may be connected to the semiconductor pattern OSP1 through a first through hole CH1 and a second through hole CH2, which pass through the first intermediate inorganic layer GI and the second intermediate inorganic layer ILD, respectively. In an embodiment, the transistor T1 may be modified to have a bottom gate structure.

The intermediate organic layer PSV covering the input electrode DE1 and the output electrode SE1 may be disposed on the second intermediate inorganic layer ILD. The intermediate organic layer PSV may provide a flat surface.

The display element layer IML may be disposed on the intermediate organic layer PSV. The display element layer IML may include a pixel defining layer PDL and an organic light emitting diode OLED. The pixel defining layer PDL may include or may be formed of an organic material. The first electrode AE may be disposed on the intermediate organic layer PSV. The first electrode AE may be connected to the output electrode SE1 through a third through hole CH3 passing through the intermediate organic layer PSV. An opening OP may be defined in the pixel defining layer PDL. The opening OP may expose at least a portion of the first electrode AE. In one embodiment, the pixel defining layer PDL may be omitted.

In one embodiment, a light emission area PXA may overlap the transistor T1.

A hole control layer HCL may be commonly disposed in light emission area PXA and a non-light emission area NPXA. A light emitting layer EML may be disposed on the hole control layer HCL. The light emitting layer EML may be disposed in an area corresponding to the opening OP. The light emitting layer EML may include or may be formed of an organic material and/or an inorganic material. The light emitting layer EML may generate a colored light of a predetermined color.

An electron control layer ECL may be disposed on the light emitting layer EML. The second electrode CE may be disposed on the electron control layer ECL.

The thin film encapsulation layer TFE may be disposed on the second electrode CE. The thin film encapsulation layer TFE may cover the second electrode CE. A capping layer (not shown) covering the second electrode CE may be further disposed between the thin film encapsulation layer TFE and the second electrode CE. The thin film encapsulation layer TFE may directly cover the capping layer (not shown).

The thin film encapsulation layer TFE may include a plurality of inorganic layers, an organic layer or their stacked structure.

In detail, the organic layer of the thin film encapsulation layer TFE is formed of a polymer and may be a single layer or stacked layer formed of any one of polyethylene terephthalate, polyimide, polycarbonate, epoxy, polyethylene and polyacrylate. In one embodiment, the organic layer may be formed of polyacrylate and specifically, includes a polymer in which a monomer composition including a diacrylate-based monomer and a triacrylate-based monomer is polymerized. The monomer composition may further include a monoacrylate-based monomer. In addition, the monomer composition may further include a known photoinitiator such as 2,4,6-trimethylbenzoyldiphenyl phosphine oxide (TPO), but is not limited thereto. The monomer composition may include epoxy, polyimide, polyethylene terephthalate, polycarbonate, polyethylene and polyacrylate.

The inorganic layer of the thin film encapsulation layer TFE may be a single layer or stacked layer, which includes a metal oxide or a metal nitride. In detail, the inorganic layer may include any one of silicon oxide (SiO₂), silicon nitride (SiN_{X}), aluminum oxide (Al₂O₃), titanium oxide (TiO₂), zirconium oxide (ZrO_{X}) and zinc oxide (ZnO). The uppermost layer of the thin film encapsulation layer TFE, which is exposed to the outside, may be formed as an inorganic layer to prevent moisture permeation to the organic light emitting element.

The thin film encapsulation layer TFE may include at least one sandwich structure in which at least one organic layer is inserted between at least two inorganic layers. As another example, the thin film encapsulation layer TFE may include at least one sandwich structure in which at least one inorganic layer is inserted between at least two organic layers. As other example, the thin film encapsulation layer TFE may include a sandwich structure in which at least one organic layer is inserted between at least two inorganic layers and a sandwich structure in which at least one inorganic layer is inserted between at least two organic layers. For example, the thin film encapsulation layer TFE may include a first inorganic layer, a first organic layer and a second inorganic layer, which are sequentially formed from the top of the organic light emitting diode OLED. For another example, the thin film encapsulation layer TFE may include a first inorganic layer, a first organic layer, a second inorganic layer, a second organic layer and a third inorganic layer, which are sequentially formed from the top of the organic light emitting diode OLED. The first organic layer may have a smaller area than the second inorganic layer, and the second organic layer may have a smaller area than the third inorganic layer. In this case, the thin film encapsulation layer TFE is not limited to the above example, and may include all structures in which an inorganic layer and an organic layer are stacked in various forms.

In concluding the detailed description, those skilled in the art will appreciate that many variations and modifications can be made to the embodiments without substantially departing from the principles of the present disclosure. Therefore, the disclosed embodiments of the present disclosure are used in a generic and descriptive sense only and not for purposes of limitation.

1. An apparatus for manufacturing a display device, the apparatus comprising:
a gas exhaust unit including:
a first sidewall and a second sidewall that face each other and are disposed side by side along a first direction,
an upper plate disposed on the first sidewall and the second sidewall,
a first partition disposed between the first sidewall and the second sidewall and extending away from a lower surface of the upper plate in a second direction that is different from the first direction,
a first main exhaust path corresponding to a first space that is defined by the first sidewall, the first partition and the upper plate, and
a second main exhaust path corresponding to a second space that is defined by the first partition, the second sidewall and the upper plate;
a gas spray unit including:
a first spray portion disposed in the first main exhaust path and spraying a first gas in the second direction, and
a second spray portion disposed in the second main exhaust path and spraying a second gas in the second direction, the second gas being different from the first gas; and
a chamber surrounding the gas exhaust unit and the gas spray unit,
wherein the first partition includes:
a first surface facing the first spray portion,
a second surface facing the second spray portion,
a third surface connecting the first surface to the second surface, wherein the third surface is spaced apart from the lower surface of the upper plate in the second direction,
a first horizontal opening formed at the first surface,
a second horizontal opening formed at the second surface,
a first vertical opening formed at the third surface, and
a first sub exhaust path connecting the first horizontal opening, the second horizontal opening, and the first vertical opening with each other.

2. The apparatus of claim 1,
wherein the first sub exhaust path includes:
a first vertical tunnel extending from the first vertical opening toward the lower surface of the upper plate in the second direction;
a first horizontal tunnel connecting the first horizontal opening to the first vertical tunnel; and
a second horizontal tunnel connecting the second horizontal opening to the first vertical tunnel.

3. The apparatus of claim 2,
wherein the first horizontal tunnel and the second horizontal tunnel are positioned at the same level relative to the third surface of the first partition, and are disposed to be closer to the upper plate than the third surface of the first partition.

4. The apparatus of claim 2,
wherein a length, in the second direction, of each of the first horizontal tunnel and the second horizontal tunnel is shorter than a length, in the second direction, of the first vertical tunnel.

5. The apparatus of claim 2,
wherein a length, in the first direction, of the first vertical tunnel is greater than or equal to a length, in the first direction, of each of the first horizontal tunnel and the second horizontal tunnel.

6. The apparatus of claim 2,
wherein the first partition further includes a first sub partition disposed in the first sub exhaust path, and
wherein the first sub partition is configured to divide the first vertical tunnel into a first sub area and a second sub area.

7. The apparatus of claim 6,
wherein the first sub partition is configured to block the first horizontal tunnel from the second horizontal tunnel.

8. The apparatus of claim 6,
wherein a length, in the second direction, of the first sub partition is longer than a length, in the second direction, of the first vertical tunnel.

9. The apparatus of claim 6,
wherein the first gas emitted from the first spray portion is emitted through the first sub area, and
wherein the second gas emitted from the second spray portion is emitted through the second sub area.

10. The apparatus of claim 9, further comprising:
a first emission pump connected to the first main exhaust path; and
a second emission pump connected to the second main exhaust path,
wherein the first gas is emitted by the first emission pump, and
wherein the second gas is emitted by the second emission pump.

11. The apparatus of claim 1,
wherein the first spray portion includes a first nozzle for spraying the first gas toward the vertical opening in the second direction,
wherein the second spray portion includes a second nozzle for spraying the second gas to the vertical opening in the second direction, and
wherein the first horizontal opening and the second horizontal opening are positioned at a higher level than the first nozzle and the second nozzle in the second direction.

12. The apparatus of claim 11,
wherein the first vertical opening is positioned at a lower level than the first nozzle and the second nozzle in the second direction.

13. The apparatus of claim 1,
wherein the first horizontal opening includes a plurality of openings arranged along a straight line extending in a third direction different from the first direction and the second direction.

14. The apparatus of claim 1,
wherein the first horizontal opening includes one opening extended along a third direction different from the first direction and the second direction.

15. The apparatus of claim 1,
wherein the first gas is a reaction gas or a source gas, and
wherein the second gas is the source gas when the first gas is the reaction gas, and is the reaction gas when the first gas is the source gas.

16. The apparatus of claim 15,
wherein the reaction gas is N₂ gas or H₂ gas,
wherein the source gas is SiH₄ gas when the reaction gas is the N₂ gas, and is HMDSO gas when the reaction gas is the H₂ gas.

17. The apparatus of claim 1, further comprising
a first storage tank for storing the first gas and a second storage tank for storing the second gas,
wherein the first storage tank is connected to the first spray portion, and the second storage tank is connected to the second spray portion.

18. An apparatus for manufacturing a display device, the apparatus comprising:
a gas exhaust unit including a plurality of main exhaust paths respectively partitioned by a plurality of partitions disposed side by side along a first direction;
a gas spray unit including a plurality of spray portions respectively disposed in the plurality of main exhaust paths and configured to spray gas in a second direction different from the first direction;
a moving unit disposed below the gas exhaust unit and the gas spray unit and configured to move a substrate;
a chamber surrounding the gas exhaust unit, the gas spray unit, and the moving unit, wherein the moving unit is configured to move the substrate in a space of the chamber under the gas exhaust unit;
a gas supply unit connected to the gas spray unit and configured to supply gas to the gas spray unit; and
a gas emission unit connected to the gas exhaust unit and configured to emit the gas exhausted from the gas exhaust unit to the outside,
wherein each partition of the plurality of partitions includes:
a horizontal tunnel connecting adjacent main exhaust paths with each other among the main exhaust paths, and
a vertical tunnel connecting the space of the chamber to the horizontal tunnel.

19. The apparatus of claim 18,
wherein each of the plurality of spray portions includes a nozzle directing toward the space of the chamber in which the moving unit moves, and
wherein the horizontal tunnel is positioned at a higher level in the second direction than the nozzle.

20. The apparatus of claim 18,
wherein a vertical length of the horizontal tunnel is shorter than a vertical length of the vertical tunnel.
